(19) United States
(12) Patent Application Publication
(10) Pub. No.: US 2024/0413180 A1
(43) Pub. Date: Dec. 12, 2024

(54) SOLID-STATE IMAGE CAPTURING APPARATUS

(71) Applicant: SONY SEMICONDUCTOR SOLUTIONS CORPORATION, KANAGAWA (JP)

(72) Inventor: IPPEI YOSHIBA, KANAGAWA (JP)

(21) Appl. No.: 18/701,955

(22) PCT Filed: Sep. 12, 2022
(86) PCT No.: PCT/JP2022/034098

§ 371 Date: Apr. 17, 2024

(30) Foreign Application Priority Data
Oct. 27, 2021 (JP) 2021-175453

(51) Int. Cl. H01L 27/146

(52) U.S. Cl. CPC H01L 27/14623; H01L 27/1463; H01L 27/14645; H01L 27/14683

(57) ABSTRACT

Provided is a solid-state image capturing apparatus that can, between an image height center and positions where the image height becomes higher, align the impact of incident light with respect to light-blocking films. The solid-state image capturing apparatus is provided with a semiconductor substrate in which multiple pixels are disposed in a matrix. Each of the multiple pixels is provided with a photoelectric conversion unit that generates charge according to photoelectric conversion based on light incident on a light-receiving surface of the semiconductor substrate, a charge accumulating unit that accumulates the charge generated by the photoelectric conversion unit, a transfer transistor that transfers charge from the photoelectric conversion unit to the charge accumulating unit and has a vertical gate electrode that reaches the photoelectric conversion unit, and a light-blocking section that is formed by a trench disposed within a layer between the light-receiving surface and the charge accumulating unit and blocks light that is incident via the light-receiving surface from being incident on the charge accumulating unit. An amount of cover by the light-blocking section with respect to the charge accumulating unit is corrected according to an image height of a position where the pixel is disposed.

### TECHNICAL FIELD

The present technique (technique according to the present disclosure) pertains to a solid-state image capturing apparatus that has a global shutter structure.

### BACKGROUND ART

In a CMOS (Complementary Metal Oxide Semiconductor) image sensor, there is a global shutter structure that is provided with a charge accumulating unit for each photodiode in order to capture a quickly-moving photographic subject without distortion. In the global shutter structure, transfer of charge from the photodiodes to the charge accumulating unit is performed for the entirety of an image capturing element array at the same time to thereby realize simultaneity for charge accumulation. However, the charge accumulating unit needs to be covered by a light-blocking layer such that new signal charge due to photoelectric conversion does not occur.

In contrast, in CMOS image sensors, there are back-illuminated image sensors that enable incident light to directly reach pixels as well as the maximization of openings for photodiodes, in order to realize higher sensitivity. Incidentally, even if a global shutter structure is formed in a back-illuminated image sensor, a charge accumulating unit is necessary, and thus there is a problem that the openings narrow, optical properties deteriorate, and a saturation charge amount also deteriorates.

In contrast to this, a back-illuminated-type global shutter CMOS image sensor in which a charge accumulating unit and a photodiode are laminated in a vertical direction has been proposed (for example, PTL 1). In a global shutter CMOS image sensor, a light-blocking structure is formed between a photodiode and a charge accumulating unit in order to cope with a noise component (PLS: Parasitic Light Sensitivity) due to light leaking into a charge accumulating unit.

### CITATION LIST

### [Patent Literature]

### [PTL 1]

Japanese Patent Laid-open No. 2013-098446

### SUMMARY

### Technical Problems

However, even with the above-described global shutter CMOS image sensor, the manner in which light makes contact with a light-blocking film changes between the image height center and a place where the image height is high, and thus it is not possible to sufficiently cope with PLS. At the image height center, it is possible to achieve sufficient cover by the light-blocking film with respect to a light-condensing spot, but cover by light-blocking films effectively shortens at an image height end, or there is direct incidence on an opening in a vertical transistor necessary for reading out charge from a photodiode, and PLS worsens.

In addition, the manner in which light comes into contact with a light-blocking film in bulk changes after the incidence of light, thus there arises an oblique incidence sensitivity characteristic that is asymmetric with respect to the angle, and the effects on image quality due to coloring, shading, or the like at the left and right with respect to the image height becomes a problem.

The present disclosure is made in light of such a situation, and an objective of the present disclosure is to provide a solid-state image capturing apparatus that can align, between an image height center and positions where the image height becomes higher, the impact of incident light with respect to light-blocking films.

### Solution to Problems

One aspect of the present disclosure is a solid-state image capturing apparatus that is provided with a semiconductor substrate in which multiple pixels are disposed in a matrix, each of the multiple pixels being provided with a photoelectric conversion unit that generates charge according to photoelectric conversion based on light incident on a light-receiving surface of the semiconductor substrate, a charge accumulating unit that accumulates the charge generated by the photoelectric conversion unit, a transfer transistor that transfers charge from the photoelectric conversion unit to the charge accumulating unit and has a vertical gate electrode that reaches the photoelectric conversion unit, and a light-blocking section that is formed by a trench disposed within a layer between the light-receiving surface and the charge accumulating unit and blocks light that is incident via the light-receiving surface from being incident on the charge accumulating unit. An amount of cover by the light-blocking section with respect to the charge accumulating unit is corrected according to an image height of a position where the pixel is disposed.

Another aspect of the present disclosure is a solid-state image capturing apparatus that is provided with a semiconductor substrate in which multiple pixels are disposed in a matrix, each of the multiple pixels being provided with a photoelectric conversion unit that generates charge according to photoelectric conversion based on light incident on a light-receiving surface of the semiconductor substrate, a charge accumulating unit that accumulates the charge generated by the photoelectric conversion unit, a transfer transistor that transfers charge from the photoelectric conversion unit to the charge accumulating unit and has a vertical gate electrode that reaches the photoelectric conversion unit, a first light-blocking section that is formed by a trench disposed within a layer between the photoelectric conversion unit and the charge accumulating unit and blocks light that is incident via the light-receiving surface from being incident on the charge accumulating unit, and a second light-blocking section that is formed by a trench disposed within a layer between the light-receiving surface and the first light-blocking section and in a position opposite to at least the first light-blocking section and blocks light that is incident via the light-receiving surface from being incident on the charge accumulating unit. Amounts of cover by the first and second light-blocking sections with respect to the charge accumulating unit are corrected according to an image height of a position where the pixel is disposed.

### BRIEF DESCRIPTION OF DRAWINGS

FIG. 1 is a block view that illustrates an example of an approximate configuration of a solid-state image capturing apparatus 1 according to a first embodiment of the present disclosure.

FIG. 2 is a circuit diagram that illustrates an example of a circuit configuration of sensor pixels and a readout circuit, according to the first embodiment of the present disclosure.

FIG. 3 is a view that illustrates an example of a cross-sectional configuration of a solid-state image capturing apparatus according to the first embodiment of the present disclosure.

FIG. 4 is a cross-sectional view that illustrates an example of a solid-state image capturing apparatus in a comparative example of an embodiment.

FIG. 5 is a view that illustrates an example of a light-condensing simulation result in the comparative example of the embodiment.

FIG. 6 is a cross-sectional view that illustrates an example of the solid-state image capturing apparatus for which an image height is a high position, in the first embodiment of the present disclosure.

FIG. 7 includes views (part 1) that illustrate an example of a process for manufacturing a solid-state image capturing apparatus according to a second embodiment of the present disclosure.

FIG. 8 is a view (part 2) that illustrates an example of a process for manufacturing the solid-state image capturing apparatus according to the second embodiment of the present disclosure.

FIG. 9 includes views (part 3) that illustrate an example of a process for manufacturing the solid-state image capturing apparatus according to the second embodiment of the present disclosure.

FIG. 10 is a view (part 4) that illustrates an example of a process for manufacturing the solid-state image capturing apparatus according to the second embodiment of the present disclosure.

FIG. 11 includes views (part 5) that illustrate an example of a process for manufacturing the solid-state image capturing apparatus according to the second embodiment of the present disclosure.

FIG. 12 is a view (part 6) that illustrates an example of a process for manufacturing the solid-state image capturing apparatus according to the second embodiment of the present disclosure.

FIG. 13 includes views (part 7) that illustrate an example of a process for manufacturing the solid-state image capturing apparatus according to the second embodiment of the present disclosure.

FIG. 14 is a view (part 8) that illustrates an example of a process for manufacturing the solid-state image capturing apparatus according to the second embodiment of the present disclosure.

FIG. 15 includes views (part 9) that illustrate an example of a process for manufacturing the solid-state image capturing apparatus according to the second embodiment of the present disclosure.

FIG. 16 includes views (part 10) that illustrates an example of a process for manufacturing the solid-state image capturing apparatus according to the second embodiment of the present disclosure.

FIG. 17 includes views (part 11) that illustrate an example of a process for manufacturing the solid-state image capturing apparatus according to the second embodiment of the present disclosure.

FIG. 18 includes views (part 12) that illustrate an example of a process for manufacturing the solid-state image capturing apparatus according to the second embodiment of the present disclosure.

FIG. 19 is a partial cross section of a sensor pixel positioned at an image height center in a solid-state image capturing apparatus according to a third embodiment of the present disclosure.

FIG. 20 is a partial cross section of a sensor pixel positioned at an image height end in the solid-state image capturing apparatus according to the third embodiment of the present disclosure.

FIG. 21 is a plan view that is seen from the back surface side of a first semiconductor substrate and illustrates a method for correcting an amount of cover by light-blocking films in a first variation of the third embodiment of the present disclosure.

FIG. 22 is a plan view that is seen from the back surface side of a first semiconductor substrate and illustrates a method for correcting an amount of cover by light-blocking films in a second variation of the third embodiment of the present disclosure.

FIG. 23 includes views (part 1) that illustrate an example of a process for manufacturing a solid-state image capturing apparatus according to a fourth embodiment of the present disclosure.

FIG. 24 is a view (part 2) that illustrates an example of a process for manufacturing the solid-state image capturing apparatus according to the fourth embodiment of the present disclosure.

FIG. 25 includes views (part 3) that illustrate an example of a process for manufacturing the solid-state image capturing apparatus according to the fourth embodiment of the present disclosure.

FIG. 26 is a view (part 4) that illustrates an example of a process for manufacturing the solid-state image capturing apparatus according to the fourth embodiment of the present disclosure.

FIG. 27 includes views (part 5) that illustrate an example of a process for manufacturing the solid-state image capturing apparatus according to the fourth embodiment of the present disclosure.

FIG. 28 is a view (part 6) that illustrates an example of a process for manufacturing the solid-state image capturing apparatus according to the fourth embodiment of the present disclosure.

FIG. 29 includes views (part 7) that illustrate an example of a process for manufacturing the solid-state image capturing apparatus according to the fourth embodiment of the present disclosure.

FIG. 30 is a view (part 8) that illustrates an example of a process for manufacturing the solid-state image capturing apparatus according to the fourth embodiment of the present disclosure.

FIG. 31 includes views (part 9) that illustrate an example of a process for manufacturing the solid-state image capturing apparatus according to the fourth embodiment of the present disclosure.

FIG. 32 includes views (part 10) that illustrate an example of a process for manufacturing the solid-state image capturing apparatus according to the fourth embodiment of the present disclosure.

FIG. 33 includes views (part 11) that illustrate an example of a process for manufacturing the solid-state image capturing apparatus according to the fourth embodiment of the present disclosure.

FIG. 34 includes views (part 12) that illustrate an example of a process for manufacturing the solid-state image capturing apparatus according to the fourth embodiment of the present disclosure.

FIG. 35 is a partial cross section of a sensor pixel positioned at an image height center in a solid-state image capturing apparatus according to a fifth embodiment of the present disclosure.

FIG. 36 is a partial cross section of a sensor pixel positioned at an image height end in the solid-state image capturing apparatus according to the fifth embodiment of the present disclosure.

FIG. 37 includes views (part 1) that illustrate an example of a manufacturing process in a case of forming light-blocking films from a front surface side of a first semiconductor substrate in a sixth embodiment of the present disclosure.

FIG. 38 includes views (part 2) that illustrate an example of a manufacturing process in the case of forming light-blocking films from the front surface side of the first semiconductor substrate in the sixth embodiment of the present disclosure.

FIG. 39 includes views (part 3) that illustrate an example of a manufacturing process in the case of forming light-blocking films from the front surface side of the first semiconductor substrate in the sixth embodiment of the present disclosure.

FIG. 40 includes views (part 4) that illustrate an example of a manufacturing process in the case of forming light-blocking films from the front surface side of the first semiconductor substrate in the sixth embodiment of the present disclosure.

FIG. 41 includes views (part 5) that illustrate an example of a manufacturing process in the case of forming light-blocking films from the front surface side of the first semiconductor substrate in the sixth embodiment of the present disclosure.

FIG. 42 includes views (part 6) that illustrate an example of a manufacturing process in the case of forming light-blocking films from the front surface side of the first semiconductor substrate in the sixth embodiment of the present disclosure.

FIG. 43 is a plan view seen from the back surface side of a first semiconductor substrate, which is illustrated in order to correct the amount of cover by light-blocking films in a seventh embodiment of the present disclosure.

FIG. 44 is a plan view seen from the back surface side of a first semiconductor substrate, which is illustrated in order to correct the amount of cover by light-blocking films in an eighth embodiment of the present disclosure.

### DESCRIPTION OF EMBODIMENTS

Embodiments of the present disclosure are described below with reference to the drawings. In the drawings referred to in the following description, the same or a similar reference sign is added to the same or similar portions, and duplicate descriptions are omitted. However, it should be noted that the drawings are schematic and differ from reality in the relation between thickness and planar dimensions, ratios of the thicknesses of respective apparatuses or members, etc. Accordingly, specific thicknesses or dimensions should be determined with reference to the following description. In addition, it goes without saying that portions are included where dimensional relations and ratios are mutually different between the drawings.

In addition, a definition of directions such as up and down in the following description is simply a definition for the convenience of the description and does not limit the technical concept of the present disclosure. For example, it goes without saying that, if a target is observed after being rotated by 90°, up and down are read as converted to left and right and, if the target is observed after being rotated by 180°, up and down are read as inverted.

Note that effects described in the present specification are purely examples, there is no limitation thereto, and there may be other effects.

### First Embodiment

### (Configuration)

Description is given regarding a solid-state image capturing apparatus 1 according to a first embodiment of the present disclosure. The solid-state image capturing apparatus 1 is a global-shutter-method back-illuminated-type image sensor that includes a CMOS (Complementary Metal Oxide Semiconductor) image sensor or the like, for example. The solid-state image capturing apparatus 1 receives light from a photographic subject, photoelectrically converts the light, and generates an image signal to thereby capture an image. The solid-state image capturing apparatus 1 outputs a pixel signal that corresponds to incident light.

The global shutter method performs global exposure in which, basically, exposure starts for all pixels at the same time, and exposure ends for all pixels at the same time. Here, “all pixels” refer to all pixels belonging to a portion that appears in an image, and dummy pixels and the like are excluded. In addition, the global shutter method also includes a method in which, instead of being simultaneous for all pixels, a region for performing global exposure moves while global exposure is performed in units of multiple rows (for example, several tens of rows) if time differences and image distortion are small enough to an extent that time differences and image distortion do not become problems. In addition, the global shutter method also includes a method for performing global exposure with respect to pixels in a predetermined region instead of all pixels in the portion that appears in an image.

A back-illuminated-type image sensor has a configuration resulting from providing, between a light-receiving surface onto which light from a photographic subject is incident and a wiring layer in which wiring for transistors and the like that drive respective pixels is provided, a photoelectric conversion unit that is a photodiode or the like, receives the light from the photographic subject, and converts the light to an electrical signal. Note that the present disclosure is not limited to application to a CMOS image sensor.

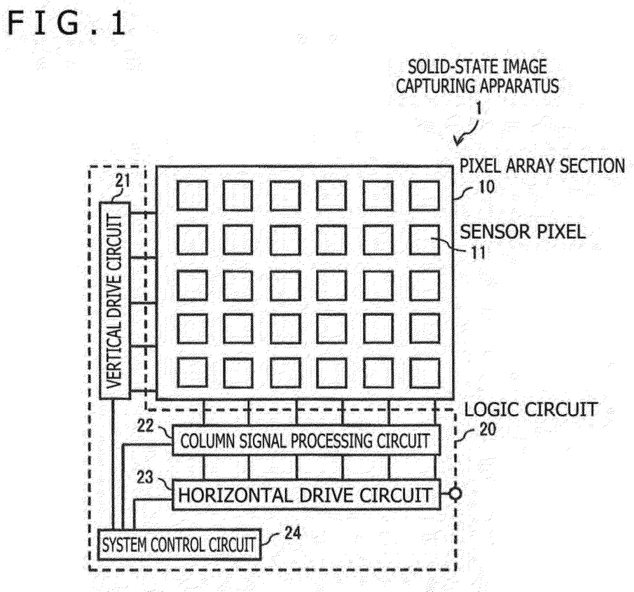

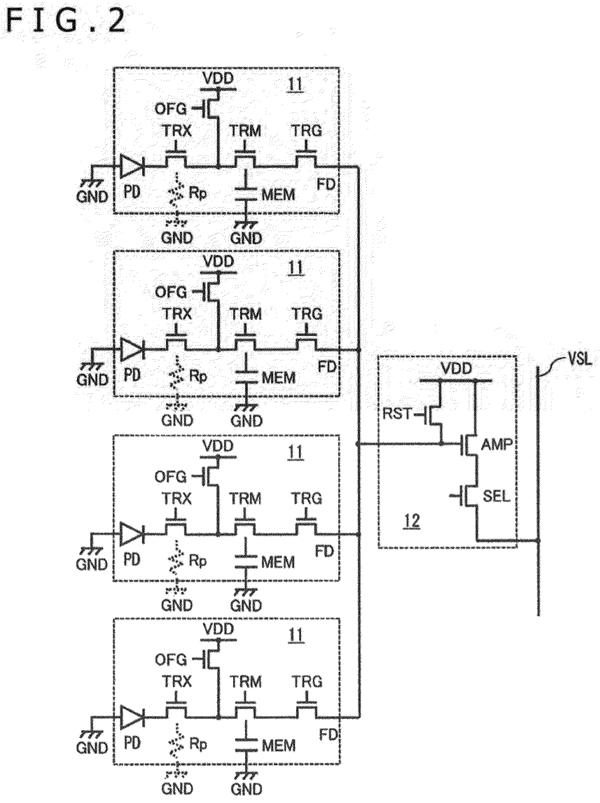

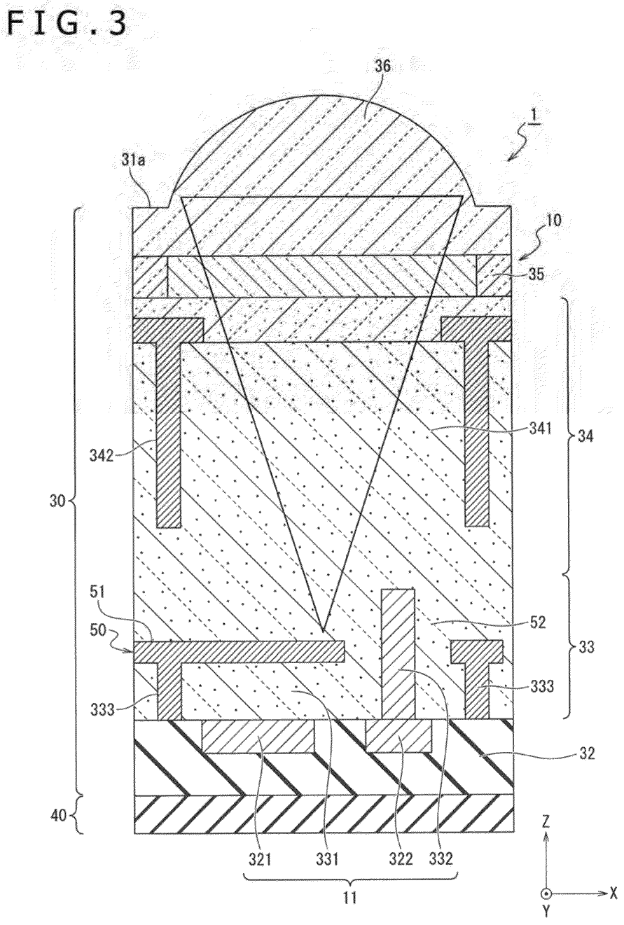

FIG. 1 represents an example of an approximate configuration of the solid-state image capturing apparatus 1 according to the first embodiment of the present disclosure. The solid-state image capturing apparatus 1 is provided with a pixel array section 10 in which multiple sensor pixels 11 that perform photoelectric conversion are arranged in a matrix. A region according to the multiple sensor pixels 11 arranged in a matrix configures what is called an “image height” that corresponds to a target space to be captured. Each sensor pixel 11 corresponds to one concrete example of a “pixel” in the present disclosure. In the present disclosure, the solid-state image capturing apparatus 1 is assumed to be what is called a back-illuminated solid-state image capturing apparatus. In a back-illuminated solid-state image capturing apparatus, the surface of a semiconductor substrate onto which light from the outside is incident is referred to as a “back surface,” and the side opposite is referred to as a “front surface.” FIG. 2 represents an example of a circuit configuration for sensor pixels 11 and a readout circuit 12 (described below). FIG. 3 represents an example of a cross-sectional configuration of a sensor pixel 11 and the readout circuit 12. The solid-state image capturing apparatus 1 is configured by, for example, pasting together two substrates (a first semiconductor substrate 30 and a second semiconductor substrate 40).

The first semiconductor substrate 30 has multiple sensor pixels 11. The multiple sensor pixels 11 are provided in a matrix at a position that faces the back surface (a light-receiving surface 31a) of the first semiconductor substrate 30. The first semiconductor substrate 30 further has multiple readout circuits 12. Each readout circuit 12 outputs a pixel signal that is based on charge outputted from a sensor pixel 11. The multiple readout circuits 12 are provided one-by-one for each four sensor pixels 11, for example. At this point, the four sensor pixels 11 share one readout circuit 12. Here, “sharing” indicates that outputs from the four sensor pixels 11 are inputted to a common readout circuit 12. Each readout circuit 12, for example, has a reset transistor RST, a selection transistor SEL, and an amplifying transistor AMP.

The first semiconductor substrate 30 has multiple pixel drive lines that extend in a row direction, and multiple data output lines VSL that extend in a column direction. A pixel drive line is wiring to which a control signal for controlling output of charge accumulated in a sensor pixel 11 is applied, and extends in the row direction, for example. A data output line VSL is wiring for outputting a pixel signal outputted from each readout circuit 12 to a logic circuit 20, and extends in the column direction, for example.

The second semiconductor substrate 40 has the logic circuit 20 that processes pixel signals. The logic circuit 20 has a vertical drive circuit 21, a column signal processing circuit 22, a horizontal drive circuit 23, and a system control circuit 24, for example. The logic circuit 20 (specifically, the horizontal drive circuit 23) externally outputs an output voltage for each sensor pixel 11.

The vertical drive circuit 21, for example, selects the multiple sensor pixels 11 in an order for each predetermined pixel row unit. The “predetermined pixel row unit” indicates pixel rows for which pixels can be selected by the same address. For example, in a case where multiple sensor pixels 11 share one readout circuit 12, when the layout of the multiple sensor pixels 11 that share the readout circuit 12 is two pixel rows×n pixel columns (n is an integer greater than or equal to 1), the “predetermined pixel row unit” indicates two pixel rows. Similarly, when the layout of the multiple sensor pixels 11 that share the readout circuit 12 is four pixel rows×n pixel columns (n is an integer greater than or equal to 1), the “predetermined pixel row unit” indicates four pixel rows.

The column signal processing circuit 22, for example, performs a correlated double sampling (CDS) process on a pixel signal outputted from each sensor pixel 11 in a row selected by the vertical drive circuit 21. The column signal processing circuit 22, for example, performs the CDS process, to thereby extract a signal level for the pixel signal and hold pixel data that corresponds to the quantity of light received by each sensor pixel 11. The horizontal drive circuit 23, for example, sequentially outputs, to an external unit, the pixel data that is being held by the column signal processing circuit 22. The system control circuit 24, for example, controls driving of each block (the vertical drive circuit 21, the column signal processing circuit 22, and the horizontal drive circuit 23) within the logic circuit 20.

Each sensor pixel 11 has components that are common to one another. Each sensor pixel 11, for example, has a photodiode PD, a first transfer transistor TRX, a second transfer transistor TRM, a charge holding unit MEM, a third transfer transistor TRG, a floating diffusion FD, and a discharge transistor OFG. The first transfer transistor TRX, the second transfer transistor TRM, the third transfer transistor TRG, and the discharge transistor OFG are NMOS (Metal Oxide Semiconductor) transistors, for example. The photodiode PD corresponds to one concrete example of a “photoelectric conversion element” in the present disclosure. The first transfer transistor TRX corresponds to one concrete example of a “transfer transistor” in the present disclosure.

The photodiode PD photoelectrically converts light that is incident via the light-receiving surface 31a. The photodiode PD performs photoelectric conversion to thereby generate charge that corresponds to the quantity of light received. The photodiode PD is, for example, a PN junction photoelectric conversion element that is configured by an N-type semiconductor region and a P-type semiconductor region that are provided inside the first semiconductor substrate 30. The cathode of the photodiode PD is electrically connected to the source of the first transfer transistor TRX, and the anode of the photodiode PD is electrically connected to a reference potential line (for example, a ground GND).

The first transfer transistor TRX is connected between the photodiode PD and the second transfer transistor TRM and, in response to a control signal applied to the gate electrode (vertical gate electrode VG) thereof, transfers charge accumulated in the photodiode PD to the second transfer transistor TRM. The first transfer transistor TRX transfers charge from the photodiode PD to the charge holding unit MEM. The first transfer transistor TRX has the vertical gate electrode VG. The drain of the first transfer transistor TRX is electrically connected to the source of the second transfer transistor TRM, and the gate of the first transfer transistor TRX is connected to a pixel drive line.

The second transfer transistor TRM is connected between the first transfer transistor TRX and the third transfer transistor TRG and, in response to a control signal applied to the gate electrode thereof, controls the potential of the charge holding unit MEM. For example, the potential of the charge holding unit MEM becomes deep when the second transfer transistor TRM is turned on, and the potential of the charge holding unit MEM becomes shallow when the second transfer transistor TRM is turned off. Then, for example, when the first transfer transistor TRX and the second transfer transistor TRM are turned on, charge accumulated in the photodiode PD is transferred to the charge holding unit MEM via the first transfer transistor TRX and the second transfer transistor TRM. The drain of the second transfer transistor TRM is electrically connected to the source of the third transfer transistor TRG, and the gate of the second transfer transistor TRM is connected to a pixel drive line.

The charge holding unit MEM is a region that, in order to realize a global shutter function, temporarily holds charge that is accumulated in the photodiode PD. The charge holding unit MEM holds charge that is transferred from the photodiode PD.

The third transfer transistor TRG is connected between the second transfer transistor TRM and the floating diffusion FD and, in response to a control signal applied to the gate electrode thereof, transfers charge held in the charge holding unit MEM to the floating diffusion FD. For example, when the second transfer transistor TRM is turned off and the third transfer transistor TRG is turned on, the charge held in the charge holding unit MEM is transferred to the floating diffusion FD via the second transfer transistor TRM and the third transfer transistor TRG. The drain of the third transfer transistor TRG is electrically connected to the floating diffusion FD, and the gate of the third transfer transistor TRG is connected to a pixel drive line.

The floating diffusion FD is a floating diffusion region that temporarily holds charge that has been outputted from the photodiode PD via the third transfer transistor TRG. For example, a reset transistor RST is connected to the floating diffusion FD, and a vertical signal line VSL is connected to the floating diffusion FD via an amplifying transistor AMP and a selection transistor SEL.

In the discharge transistor OFG, the drain thereof is connected to a power supply line VDD, and the source thereof is connected between the first transfer transistor TRX and the second transfer transistor TRM. The discharge transistor OFG initializes (resets) the photodiode PD in response to a control signal applied to the gate electrode thereof. For example, when the first transfer transistor TRX and the discharge transistor OFG are turned on, the potential of the photodiode PD is reset to the potential level of the power supply line VDD. In other words, the photodiode PD is initialized. In addition, for example, the discharge transistor OFG forms an overflow path between the first transfer transistor TRX and the power supply line VDD, and discharges charge that overflows from the photodiode PD to the power supply line VDD.

In the reset transistor RST, the drain thereof is connected to the power supply line VDD, and the source thereof is connected to the floating diffusion FD. The reset transistor RST, in response to a control signal applied to the gate electrode thereof, initializes (resets) each region from the charge holding unit MEM to the floating diffusion FD. For example, when the third transfer transistor TRG and the reset transistor RST are turned on, the potentials of the charge holding unit MEM and the floating diffusion FD are reset to the potential level of the power supply line VDD. In other words, the charge holding unit MEM and the floating diffusion FD are initialized.

In the amplifying transistor AMP, the gate electrode thereof is connected to the floating diffusion FD and the drain thereof is connected to the power supply line VDD, and the amplifying transistor AMP thereby becomes an input unit for a source follower circuit that reads out charge obtained by photoelectric conversion in the photodiode PD. In other words, the amplifying transistor AMP, by the source being connected to the vertical signal line VSL via the selection transistor SEL, configures a source follower circuit and a constant-current source that is connected to one end of the vertical signal line VSL.

The selection transistor SEL is connected between the source of the amplifying transistor AMP and the vertical signal line VSL, and a control signal as a selection signal is supplied to the gate electrode of the selection transistor SEL. The selection transistor SEL enters a conductive state when the control signal is turned on, and the sensor pixels 11 connected to the selection transistor SEL enter a selected state. When the sensor pixels 11 enter the selected state, a pixel signal outputted from the amplifying transistor AMP is read out by the column signal processing circuit 22 via the vertical signal line VSL.

### (Cross-Sectional Structure)

Schematically, the first semiconductor substrate 30 is configured by including, for example, a wiring layer 32, an MEM layer 33, a photoelectric conversion layer 34, a color filter 35, and an on-chip lens 36. In addition, the first semiconductor substrate 30 of the present disclosure includes a light-blocking film 50. The second semiconductor substrate 40 is used for supporting various layers that are formed in a semiconductor manufacturing process.

The on-chip lens 36 is an optical lens for efficiently condensing light, which is incident on the solid-state image capturing apparatus 1 from the outside, to thereby form an image on respective sensor pixels 11 in the photoelectric conversion layer 34. The on-chip lens 36 is typically disposed for each sensor pixel 11. In addition, the on-chip lens 36 is disposed according to what is called pupil correction in order to effectively use light at a place where the image height of the solid-state image capturing apparatus 1 is high. Note that the on-chip lens 36 includes silicon oxide, silicon nitride, silicon oxynitride, organic SOG, a polyimide resin, a fluorine resin, or the like, for example.

The color filter 35 is an optical filter that, from among light condensed by the on-chip lens 36, selectively transmits light that has a predetermined wavelength. In the present example, four color filters 35 that selectively transmit wavelengths for red light, green light, blue light, and near-infrared light, respectively, are used, but there is no limitation to this. A color filter 35 corresponding to one color (wavelength) is disposed for each sensor pixel 11.

The photoelectric conversion layer 34 is a functional layer in which is formed a photoelectric conversion element 341 such as photodiode PD that is included in each sensor pixel 11. Each photoelectric conversion element 341 in the photoelectric conversion layer 34 generates an amount of charge, which corresponds to the intensity of light that is incident via the on-chip lens 36 and the color filter 35, converts this to an electrical signal, and outputs the electrical signal as a pixel signal. Note that some of the light (such as near-infrared light, for example) that is incident on an incident surface belonging to the photoelectric conversion layer 34 can pass through to the surface on the side opposite (in other words, the front surface) with respect to the light-receiving surface 31a (in other words, the back surface). The photoelectric conversion layer 34 is prepared on a silicon substrate using a semiconductor manufacturing process. In addition, a back-surface pixel separation section 342 for separating sensor pixels 11 from each other can be formed in the photoelectric conversion layer 34. The back-surface pixel separation section 342 includes a trench structure that is formed by an etching process, for example. The back-surface pixel separation section 342 prevents light that is incident on a sensor pixel 11 from entering into an adjacent sensor pixel 11.

The MEM layer 33 is a functional layer in which a charge holding region 331 such as the charge holding unit MEM included in each sensor pixel 11 and a vertical gate electrode 332 such as the first transfer transistor TRX are formed. The vertical gate electrode 332 reaches the photoelectric conversion layer 34. Charge generated by the photoelectric conversion element 341 is transferred to the charge holding region 331 via the first transfer transistor TRX and is accumulated in the charge holding region 331. The photoelectric conversion element 341, the charge holding region 331, and the first transfer transistor TRX are electrically connected by predetermined metal wiring in the wiring layer 32. Note that the charge holding region 331 is connected to a transistor base section 321 that configures the second transfer transistor TRM, and the vertical gate electrode 332 for the first transfer transistor TRX is connected to a transistor base section 322. In addition, a front-surface pixel separation section 333, which separates sensor pixels 11 from each other, can be formed in the MEM layer 33. The front-surface pixel separation section 333 includes a trench structure that is formed by an etching process, for example. The front-surface pixel separation section 333 prevents light that is incident on a sensor pixel 11 from entering into an adjacent sensor pixel 11.

Formed in the wiring layer 32 includes a metal wiring pattern for transmitting power and various drive signals to each sensor pixel 11 in the MEM layer 33 and the photoelectric conversion layer 34 and for transmitting a pixel signal read out from each sensor pixel 11. Typically, the wiring layer 32 can be formed by laminating multiple metal wiring patterns with interlayer insulating films interposed therebetween. In addition, the laminated metal wiring patterns are electrically connected by a via, for example, if necessary. The wiring layer 32 is formed using a metal such as aluminum (Al) or copper (Cu), for example. In contrast, each interlayer insulating film is formed using silicon oxide, or the like, for example.

The light-blocking film 50 is disposed within the MEM layer 33, is connected to the front-surface pixel separation section 333, and is formed using a light-block formation trench 51 that extends in a direction (direction indicated by the arrow X in FIG. 3) that is orthogonal to the front-surface pixel separation section 333. Note that the light-block formation trench 51 may be formed to extend in a direction indicated by the arrow Y in FIG. 3. The light-blocking film 50 blocks incidence of light, which is incident via the light-receiving surface 31a, onto the charge holding region 331. In addition, the light-blocking film 50 has an opening 52 through which the vertical gate electrode 332 for the first transfer transistor TRX penetrates.

### Comparative Example of Embodiment

Incidentally, in a case where consideration is given to an actual sensor chip, the manner in which light makes contact with the light-blocking film 50 changes between the image height center and a place where the image height is high, and thus it is not possible to sufficiently cope with PLS.

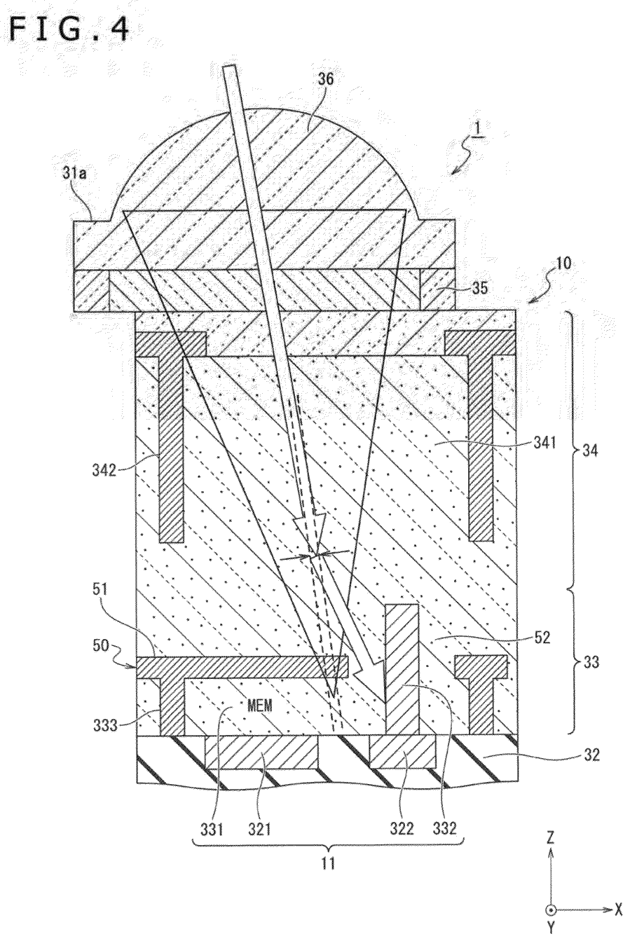

FIG. 4 is a cross-sectional view that illustrates an example of a solid-state image capturing apparatus 1 in a comparative example. In FIG. 4, the same reference signs are added, and detailed description is omitted for portions that are the same as those in FIG. 3 described above.

In the comparative example, at an image height end, cover for the light-blocking film 50 effectively becomes smaller, or there is incidence on the opening 52 for the vertical gate electrode 332 for the first transfer transistor TRX necessary for reading out charge from the photoelectric conversion element 341, and PLS worsens. In addition, the manner in which light comes into contact with the light-blocking film 50 in bulk changes after the incidence of light, thus there arises an oblique incidence sensitivity characteristic that is asymmetric with respect to the angle, and the effects on image quality due to coloring, shading, or the like at the left and right with respect to the image height becomes a problem.

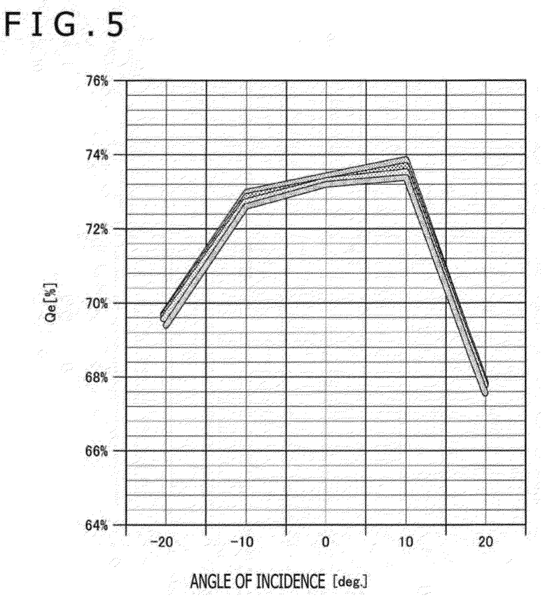

FIG. 5 illustrates an example of a light-condensing simulation result. In FIG. 5, the horizontal axis illustrates an angle of incidence for light having a wavelength of 600 nm from −20° to +20°, and the vertical axis indicates a light-condensing output. As illustrated in FIG. 5, it is understood that the output is symmetrical from −20° to +20°. In other words, an impact due to light being reflected or scattered by the light-blocking structure in the horizontal direction can be seen.

### Solution in First Embodiment

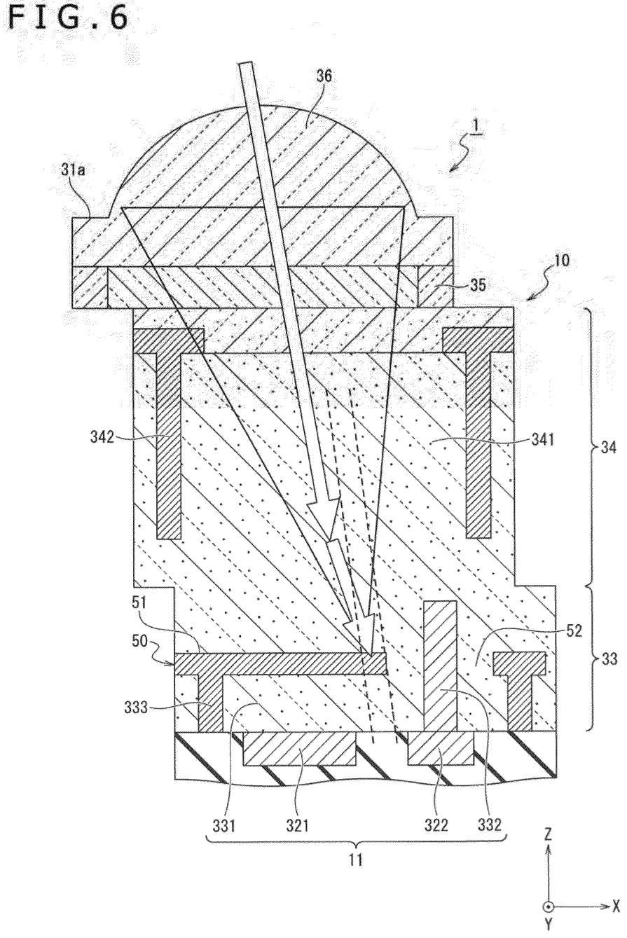

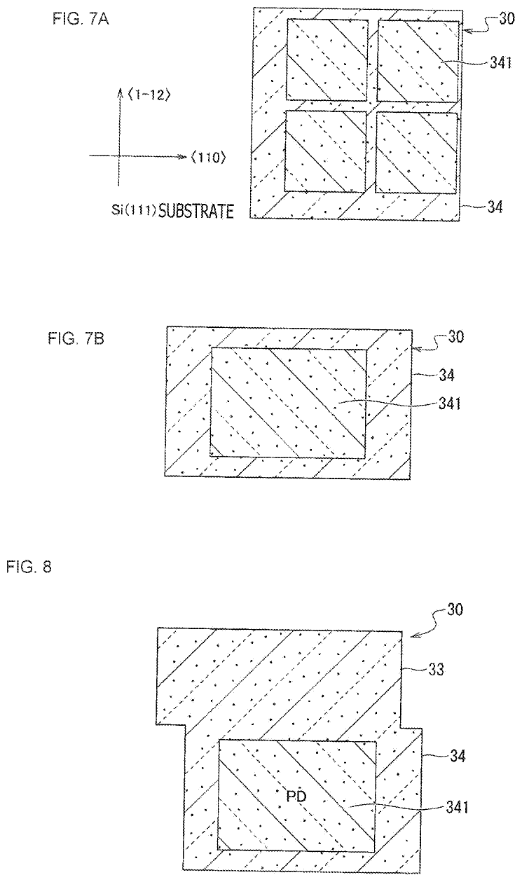

With respect to the problem described above, a measure taken in the first embodiment of the present disclosure, as illustrated in FIG. 6, is to apply corrections such that the amount of cover by the light-blocking film 50 in the horizontal direction (direction indicated by the arrow X in FIG. 6) that is orthogonal to the front-surface pixel separation section 333 and the back-surface pixel separation section 342 is the same at places where the image height is high and at the image height center.

In the first embodiment of the present disclosure, the photoelectric conversion layer 34 is disposed according to pupil correction. In other words, the photoelectric conversion layer 34 corresponding to a sensor pixel 11 positioned at the image height center (image height zero) is disposed such that the center thereof substantially matches the center of the MEM layer 33, that is, the center of the sensor pixel 11. In contrast, as illustrated in FIG. 6, the more the position is closer to the image height end (the higher the image height), the more the photoelectric conversion layer 34 is shifted from the center of the MEM layer 33, that is, the center of the sensor pixel 11. In other words, the more the position is closer to the image height end, the more the position of the photoelectric conversion layer 34 is shifted from the center of the MEM layer 33 in alignment with the direction in which a primary ray of light is emitted. The structure is such that the position of the back-surface pixel separation section 342 is shifted from the position of the opening 52 in the light-blocking film 50. By virtue of such pupil correction, the amount of cover for the light-blocking film 50 with respect to incident light can approach that for the image height center.

### Operation Effect According to the First Embodiment

By virtue of the first embodiment as above, for a sensor pixel 11 at a position where the image height is high, pupil correction is performed in which the photoelectric conversion layer 34 is shifted in a predetermined direction from the center of the MEM layer 33, that is, the center of the sensor pixel 11, whereby it is possible for the amount of cover for the light-blocking film 50 with respect to incident light to approach that for the image height center. As a result, it is possible to cause the impact of incident light with respect to the light-blocking film 50 to be aligned between the image height center and positions where the image height is high, and it is possible to improve image height dependence for an oblique incidence characteristic and PLS that impact image quality such as coloring or shading at the left and right for the image height.

### Second Embodiment

In a second embodiment of the present disclosure, description is given regarding a method of manufacturing a solid-state image capturing apparatus 1. FIGS. 7 through 18 represent an example of processes for manufacturing the solid-state image capturing apparatus 1.

First, as illustrated in FIG. 7, a photoelectric conversion layer 34 that includes a silicon substrate having a (111) crystal orientation and in which the multiple photoelectric conversion elements 341 (four photoelectric conversion elements 341 are formed in FIG. 7) are formed is prepared in the first semiconductor substrate 30. FIG. 7 (a) illustrates a plane for the photoelectric conversion layer 34, and FIG. 7 (b) illustrates a cross-sectional structure of the photoelectric conversion layer 34. The multiple photoelectric conversion elements 341 are formed along a <1-12> direction and a <110> direction in FIG. 7.

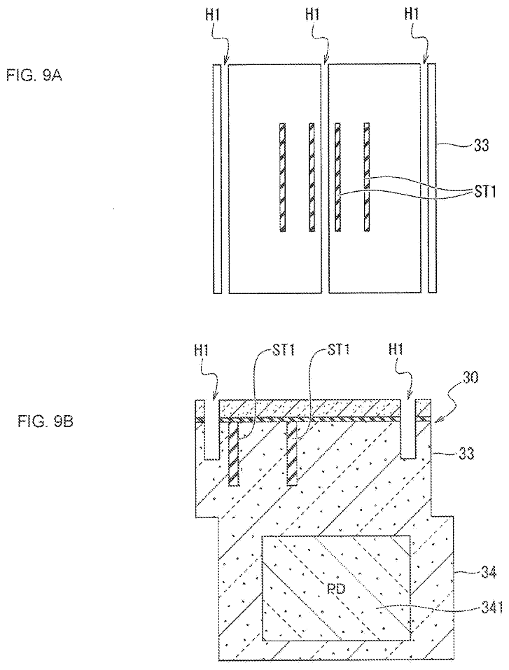

Next, epitaxial growth is used to deposit the MEM layer 33 on the top surface of the photoelectric conversion layer 34, and the MEM layer 33 is shifted with respect to the photoelectric conversion layer 34 according to an image height (FIG. 8). Next, as illustrated in FIG. 9, at predetermined locations in the MEM layer 33, trenches H1 for pixel separation as well as stoppers ST1 for forming openings 52 in the light-blocking film 50 are formed. FIG. 9 (a) illustrates a plane for the MEM layer 33, and FIG. 9 (b) illustrates a cross-sectional structure of the MEM layer 33 and the photoelectric conversion layer 34.

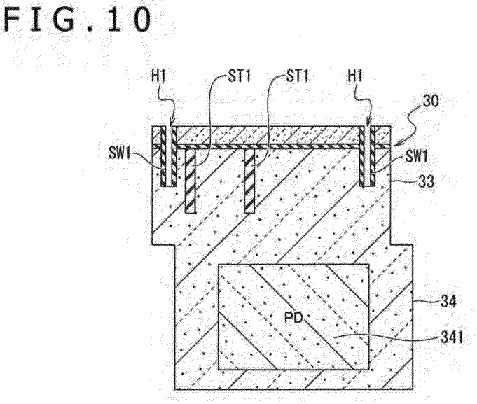

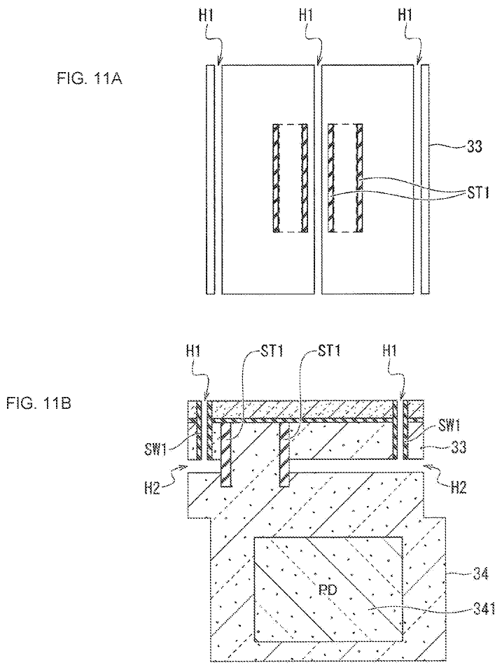

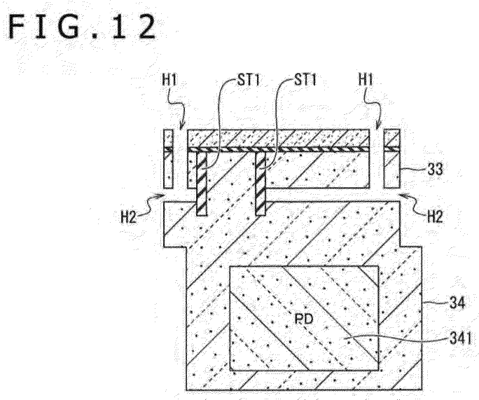

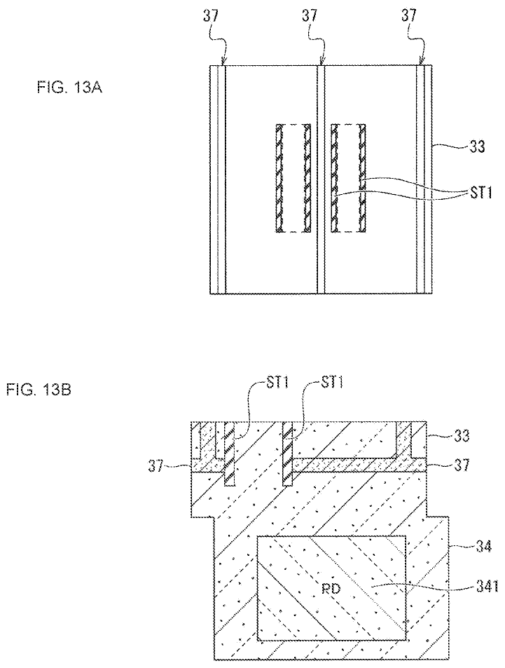

Next, sidewalls SW1 are formed on the side walls of the trenches H1 (FIG. 10), wet etching that uses an alkaline solution is used to form trenches H2 at predetermined locations within the MEM layer 33 (FIG. 11), and after that, the sidewalls SW1 formed at the side walls of the trenches H1 are removed (FIG. 12).

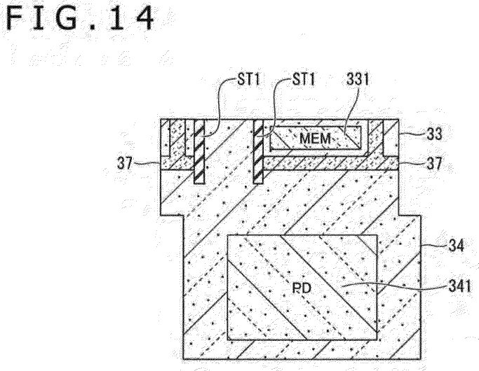

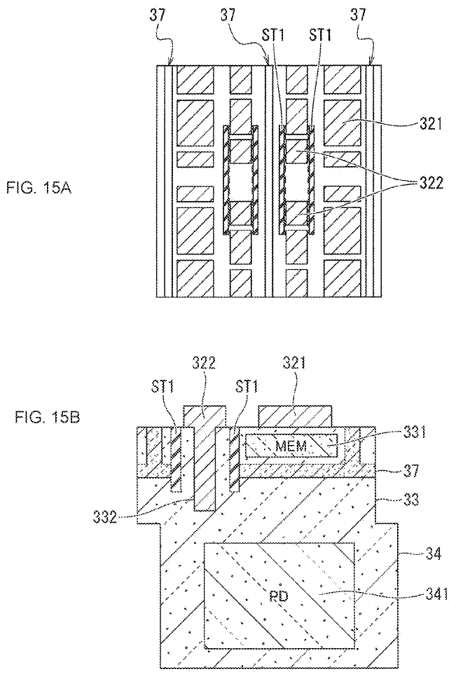

Next, the MEM layer 33 is made thin, for example, silicon is embedded in the trenches H1 and the trenches H2 to thereby form temporary embedded sections 37 (FIG. 13), and the charge holding region 331 for the charge holding unit MEM is formed in the MEM layer 33 (FIG. 14).

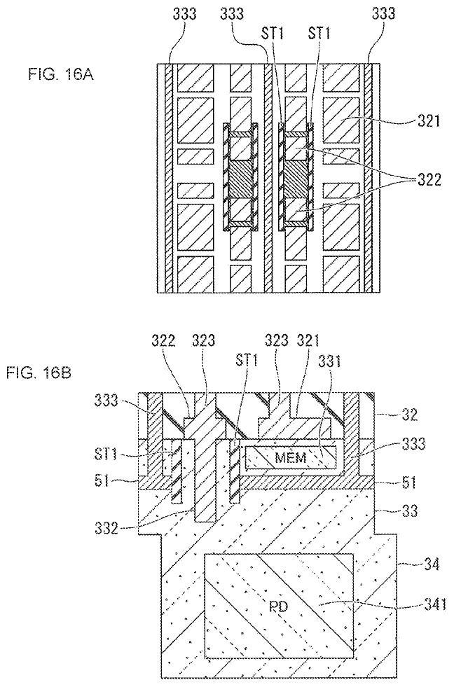

Next, the vertical gate electrode 332 is formed between stoppers ST1 in the MEM layer 33, and furthermore, the transistor base section 321 that configures the second transfer transistor TRM and the transistor base section 322 that configures the first transfer transistor TRX are formed on the top surface (front surface) of the MEM layer 33 (FIG. 15 (b)). Note that, as illustrated in FIG. 15 (a), multiple other transistor base sections 320 are formed on the front surface of the MEM layer 33.

Next, the temporary embedded sections 37 are removed, tungsten (W), for example, is embedded in the trenches H1 and the trenches H2 to thereby form the light-block formation trenches 51 for the light-blocking film 50 and the front-surface pixel separation section 333, and the wiring layer 32 is formed on the front surface of the MEM layer 33 (FIG. 16 (b)). At this point, metal wiring 323 for connecting to other circuits is formed on the transistor base sections 321 and 322. Note that, as illustrated in FIG. 16 (a), the metal wiring 323 is also formed on the top surface of the multiple other transistor base sections 320.

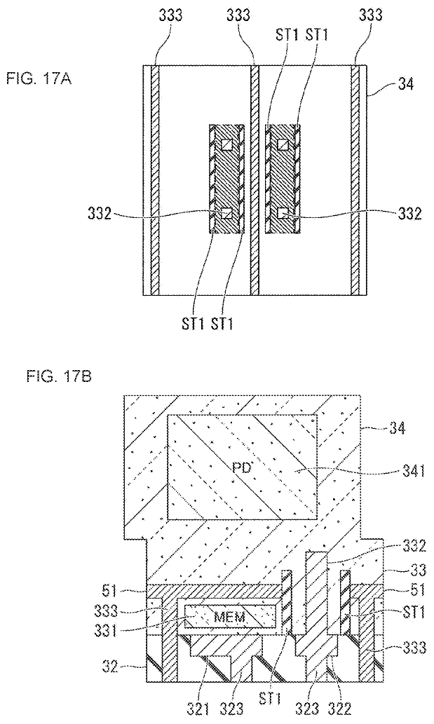

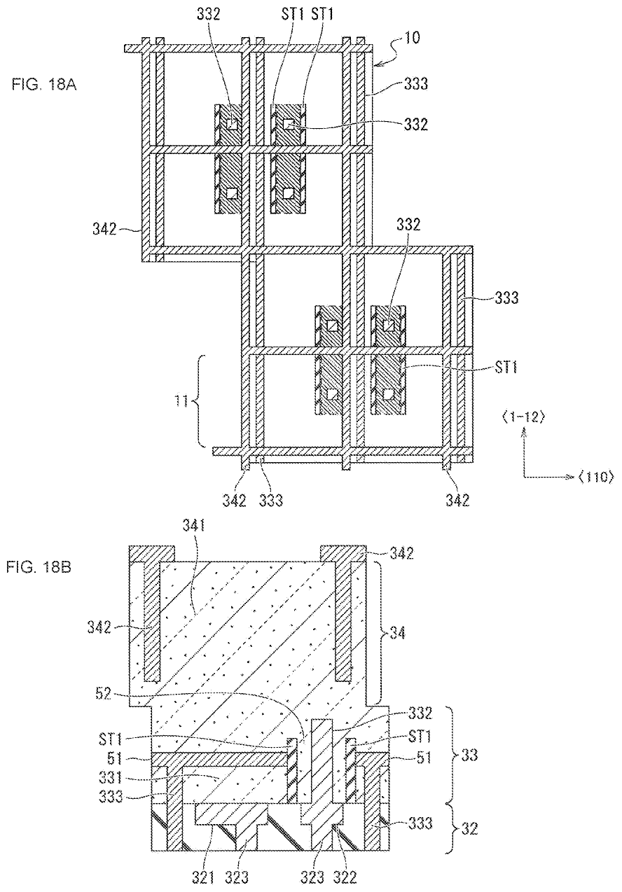

Next, the wiring layer 32, the MEM layer 33, and the photoelectric conversion layer 34 are reversed from the state in FIG. 16 (b), and the photoelectric conversion layer 34 is made thin (FIG. 17). Subsequently, trenches for pixel separation are formed at predetermined locations in the photoelectric conversion layer 34, and tungsten (W), for example, is embedded in the trenches to thereby form the back-surface pixel separation section 342 (FIG. 18 (b)). At this point, as illustrated in FIG. 18A, the back-surface pixel separation section 342 is shifted and disposed in the reverse direction to the arrow <110> direction in FIG. 18A with respect to the front-surface pixel separation section 333, according to an image height. In FIG. 18A, the sensor pixels 11 are surrounded in a grid shape by the front-surface pixel separation section 333 and the back-surface pixel separation section 342.

### Third Embodiment

In a third embodiment of the present disclosure, description is given regarding a two-level light-blocking structure.

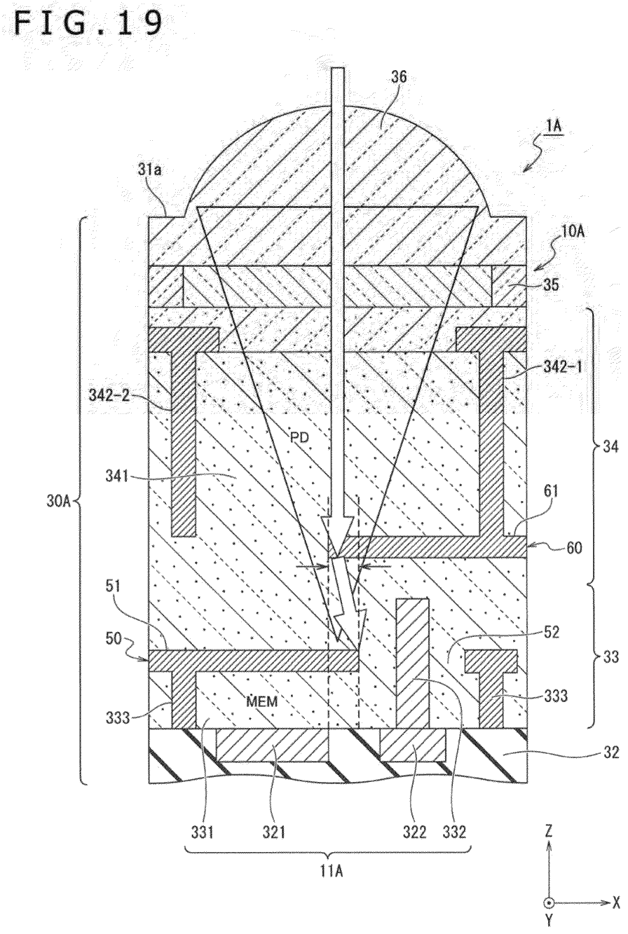

FIG. 19 is a partial cross section of a sensor pixel 11A in a solid-state image capturing apparatus 1A according to a third embodiment of the present disclosure. In FIG. 19, the same reference signs are added, and detailed description is omitted for portions that are the same as those in FIG. 3 described above.

In the third embodiment of the present disclosure, the above-described light-blocking film 50 is formed at a first level, and a second-level light-blocking film 60 is also formed, in a first semiconductor substrate 30A for a pixel array section 10A. The light-blocking film 60 is formed using a layer between the light-receiving surface 31a and the light-blocking film 50, in other words, a light-block formation trench 61 disposed within the photoelectric conversion layer 34, and blocks incidence of light that is incident via the light-receiving surface 31a onto the charge holding region 331. The light-block formation trench 61, for example, is connected to a back-surface pixel separation section 342-1 on the right side in FIG. 19, and extends in a direction (direction indicated by the arrow X in FIG. 19) that is orthogonal to the back-surface pixel separation section 342-1. Note that the light-block formation trench 61 may be formed to extend in a direction indicated by the arrow Y in FIG. 19.

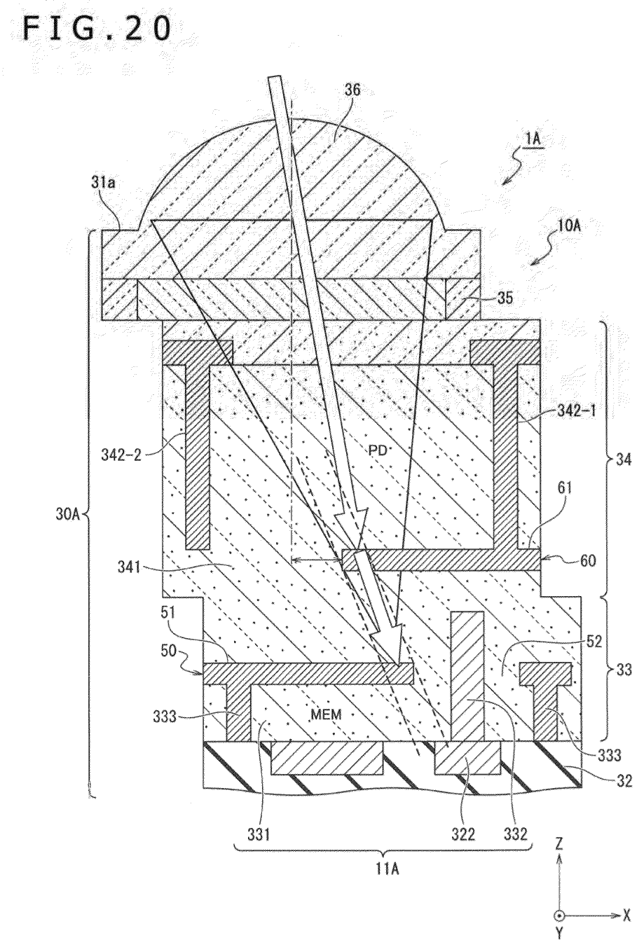

In the third embodiment of the present disclosure, the photoelectric conversion layer 34 is disposed according to pupil correction, as in the first embodiment described above. In other words, as illustrated in FIG. 19, the photoelectric conversion layer 34 corresponding to a sensor pixel 11A positioned at the image height center (image height zero) is disposed such that the center thereof substantially matches the center of the MEM layer 33, that is, the center of the sensor pixel 11A. In contrast, as illustrated in FIG. 20, the more the position is closer to the image height end (the higher the image height), the more the photoelectric conversion layer 34 is shifted from the center of the MEM layer 33, that is, the center of the sensor pixel 11A. In other words, the more the position is closer to the image height end, the more the position of the photoelectric conversion layer 34 is shifted from the center of the MEM layer 33 in alignment with the direction in which a primary ray of light is emitted.

An amount of protrusion by the light-block formation trench 61 in the direction indicated by the arrow X in FIG. 20 is corrected according to an image height to thereby correct the amount of cover by the light-blocking film 60.

### Operation Effect According to the Third Embodiment

By virtue of the third embodiment as above, in addition to pupil correction in which the photoelectric conversion layer 34 is shifted from the center of the MEM layer 33, in other words, the center of the sensor pixel 11A according to an image height, the amount of cover by the second-level light-blocking film 60 is corrected, whereby it is possible to cause the impact of incident light with respect to the light-blocking films 50 and 60 to be aligned between the image height center and positions where the image height is high, and it is possible to further improve image height dependence for an oblique incidence characteristic and PLS that impact image quality such as coloring or shading at the left and right for the image height.

### First Variation of Third Embodiment

In a first variation of the third embodiment, description is given regarding a case where a second-level light-block formation trench has a l-shaped pattern.

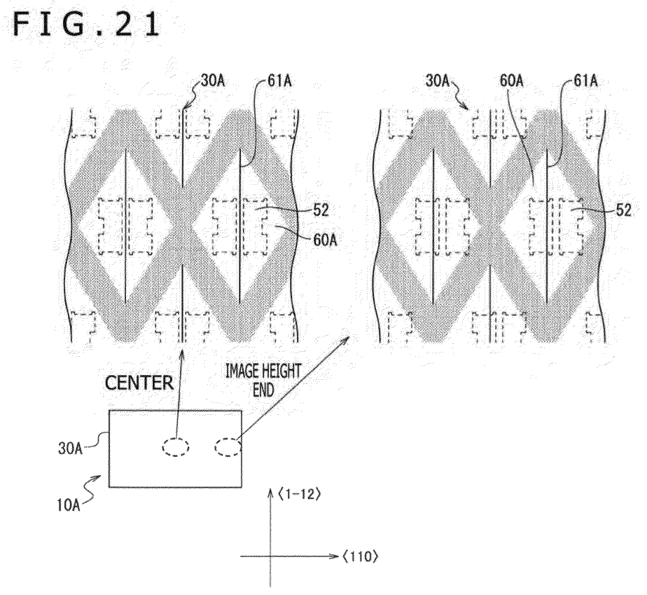

FIG. 21 is a plan view seen from the back surface side of the first semiconductor substrate 30A, which is illustrated in order to correct the amount of cover by light-blocking films in the first variation of the third embodiment of the present disclosure. In FIG. 21, the same reference signs are added, and detailed description is omitted for portions that are the same as those in FIG. 19 described above.

In the first variation of the third embodiment of the present disclosure, light-block formation trenches 61A having a l-shaped pattern are connected to back-surface pixel separation sections 342-1 and 342-2. The light-block formation trenches 61A having the l-shaped pattern extend in the arrow <1-12> direction in FIG. 21, and form substantially diamond-shaped light-blocking films 60A.

In the first variation of the third embodiment of the present disclosure, it is not possible to correct the amount of cover itself for the second-level light-blocking film 60A, and thus, as in the one-level light-blocking structure, pupil correction that shifts the photoelectric conversion layer 34 with respect to the MEM layer 33 is used to correct the amount of cover by the light-blocking film 60A. The light-block formation trenches 61A having the l-shaped pattern are further shifted from the openings 52 in the first-level light-blocking film 50, as the light-block formation trenches 61A are positioned toward an image height end.

### Operation Effect According to First Variation of Third Embodiment

By virtue of the first variation of the third embodiment as above, it is possible to improve PLS, which impacts image quality such as coloring or shading at the left and right for the image height.

### Second Variation of Third Embodiment

In a second variation of the third embodiment, description is given regarding a case where a second-level light-block formation trench has an I-shaped pattern.

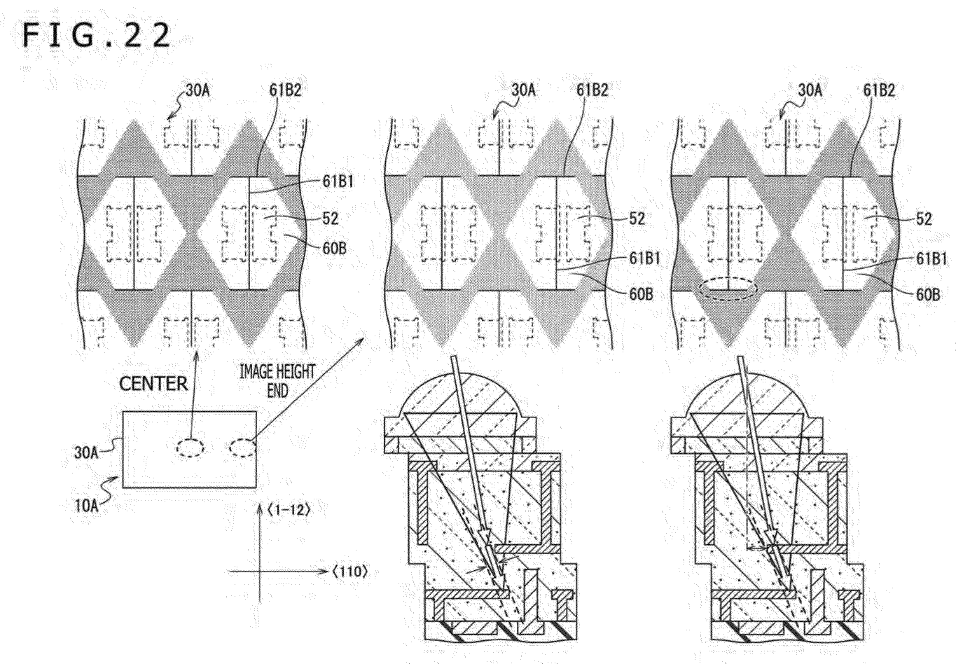

FIG. 22 is a plan view seen from the back surface side of the first semiconductor substrate 30A, which is illustrated in order to correct the amount of cover by light-blocking films in the second variation of the third embodiment of the present disclosure. In FIG. 22, the same reference signs are added, and detailed description is omitted for portions that are the same as those in FIG. 21 described above.

In the second variation of the third embodiment of the present disclosure, light-block formation trenches 61B1 and 61B2 having an I-shaped pattern are connected to back-surface pixel separation sections 342-1 and 342-2. The light-block formation trench 61B1 extends in the arrow <1-12> direction in FIG. 22, and the light-block formation trench 61B2 extends in the arrow <110> direction in FIG. 22. The light-block formation trenches 61B1 and 61B2 that have I-shaped patterns form substantially hexagonal light-blocking films 60B.

In the second variation of the third embodiment of the present disclosure, it is possible to correct the amount of cover itself by the second-level light-blocking film 60B. In this case, the amount of protrusion by the light-block formation trench 61B2 that extends in the <110> direction is made different between the left and right to thereby correct the amount of cover by the light-blocking film 60B. In other words, the amount of protrusion by a light-block formation trench 61B2 close to an image height end is increased, whereby it is possible to perform a correction to the direction in which light comes into contact with the light-blocking film 60B such that the direction is the same as that for the image height center even if the image height increases. In addition, as in a one-level light-blocking structure, combination with pupil correction that shifts the photoelectric conversion layer 34 with respect to the MEM layer 33 is also possible. In the case of a two-level light-blocking structure, light blocking deeper from the light-receiving surface 31a has a larger eccentricity for a light-condensing spot, and thus an amount of correction also increases. Accordingly, the amount of correction for the photoelectric conversion layer 34 with respect to the MEM layer becomes greater than the amount of correction for the second-level light-blocking film 60B.

### Operation Effect According to Second Variation of Third Embodiment

By virtue of the second variation of the third embodiment as above, in a case where the second-level light-blocking film 60B is formed by the light-block formation trench 61B1 that extends in the <1-12> direction and the light-block formation trench 61B2 that extends in the <110> direction which is orthogonal to the <1-12> direction, the amount of protrusion by the light-block formation trench 61B2 that extends in the <110> direction is changed at the left or right according to an image height, whereby it is possible to correct the amount of cover by the light-blocking film 60B.

In addition, by virtue of the second variation of the third embodiment, the amount of protrusion by a light-block formation trench 61B2 close to an image height end is increased, whereby it is possible to perform a correction to the direction in which light comes into contact with the light-blocking film 60B such that the direction is the same as that for the image height center even if the image height increases.

### Fourth Embodiment

In a fourth embodiment of the present disclosure, description is given regarding a method of manufacturing a solid-state image capturing apparatus 1A that has a two-level light-blocking structure. FIG. 23 through FIG. 34 each represent an example of a process for manufacturing the solid-state image capturing apparatus 1A.

First, as illustrated in FIG. 23, a photoelectric conversion layer 34, which includes a silicon substrate having a (111) crystal orientation and in which the multiple photoelectric conversion elements 341 are formed (four photoelectric conversion elements 341 are formed in FIG. 23), is prepared in the first semiconductor substrate 30. FIG. 23 (a) illustrates a plane for the photoelectric conversion layer 34, and FIG. 23 (b) illustrates a cross-sectional structure of the photoelectric conversion layer 34. The multiple photoelectric conversion elements 341 are formed along a <1-12> direction and a <110> direction in FIG. 23.

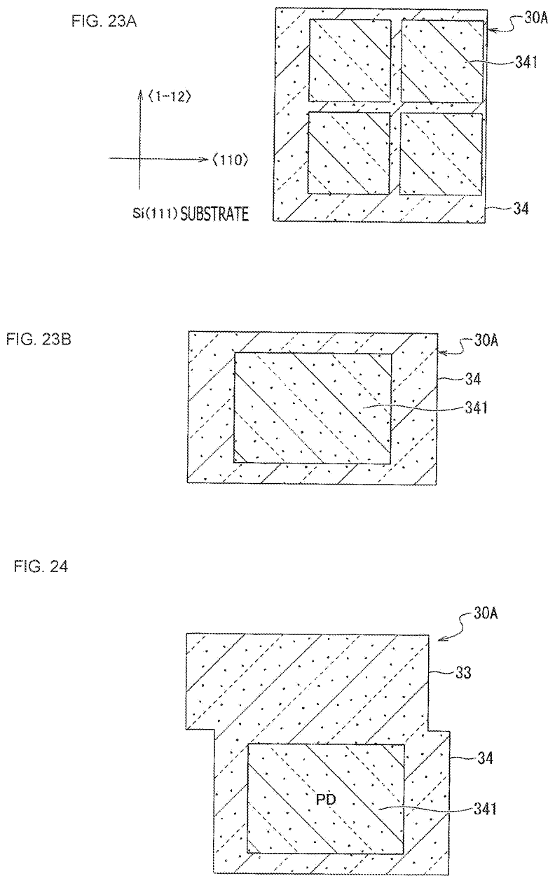

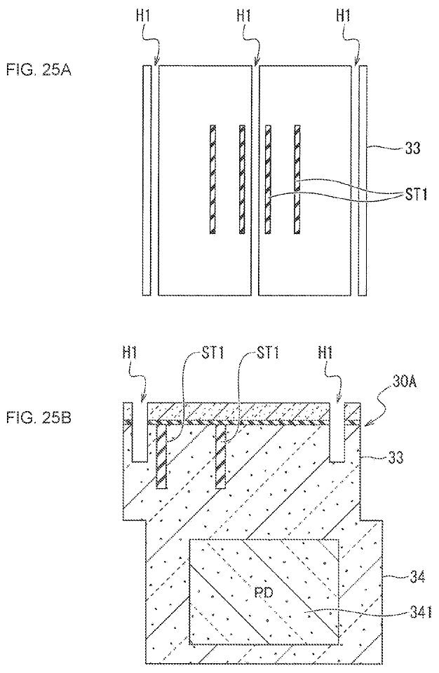

Next, epitaxial growth is used to deposit the MEM layer 33 on the top surface of the photoelectric conversion layer 34, and the MEM layer 33 is shifted with respect to the photoelectric conversion layer 34 according to an image height (FIG. 24). Next, as illustrated in FIG. 25, at predetermined locations in the MEM layer 33, trenches H1 for pixel separation as well as stoppers ST1 for forming openings 52 in the light-blocking film 50 are formed. FIG. 25 (a) illustrates a plane for the MEM layer 33, and FIG. 25 (b) illustrates a cross-sectional structure of the MEM layer 33 and the photoelectric conversion layer 34.

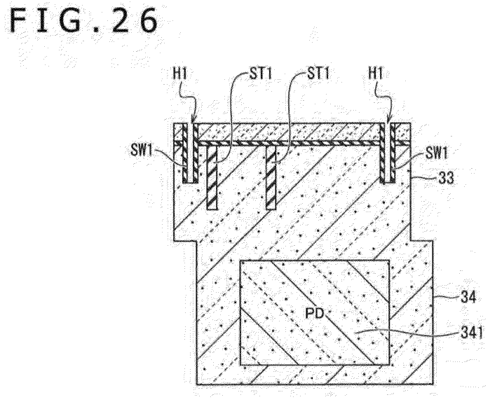

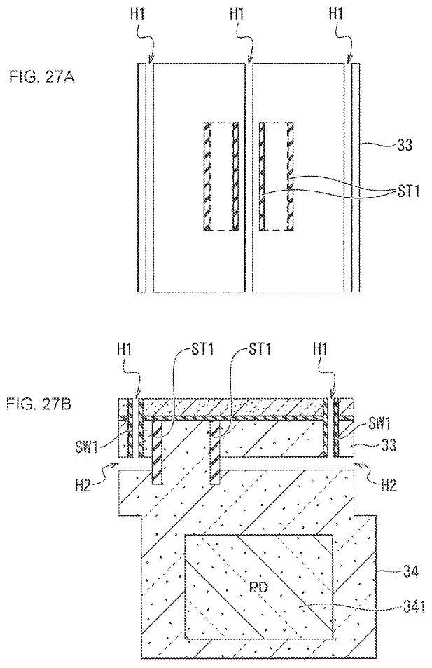

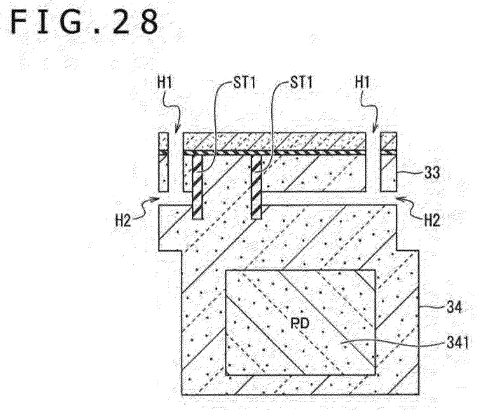

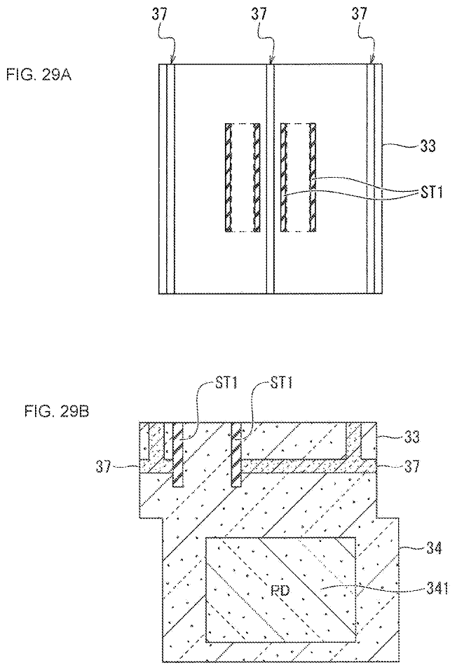

Next, sidewalls SW1 are formed on the side walls of the trenches H1 (FIG. 26), wet etching that uses an alkaline solution is used to form trenches H2 at predetermined locations within the MEM layer 33 (FIG. 27), and after that, the sidewalls SW1 formed at the side walls of the trenches H1 are removed (FIG. 28).

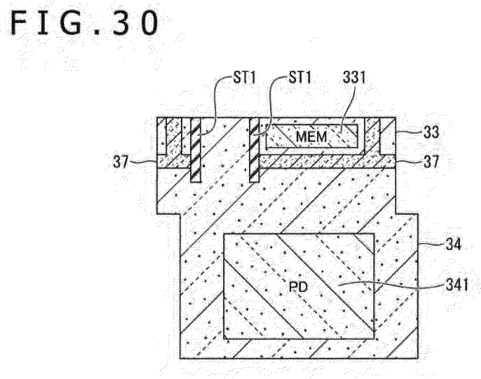

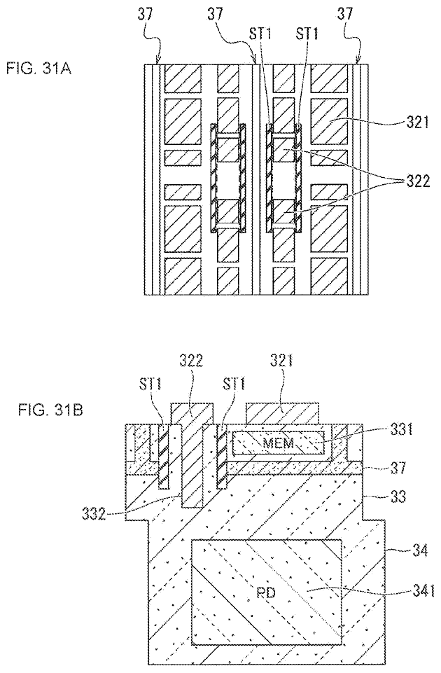

Next, the MEM layer 33 is made thin, silicon, for example, is embedded in the trenches H1 and the trenches H2 to thereby form temporary embedded sections 37 (FIG. 29), and the charge holding region 331 for the charge holding unit MEM is formed in the MEM layer 33 (FIG. 30).

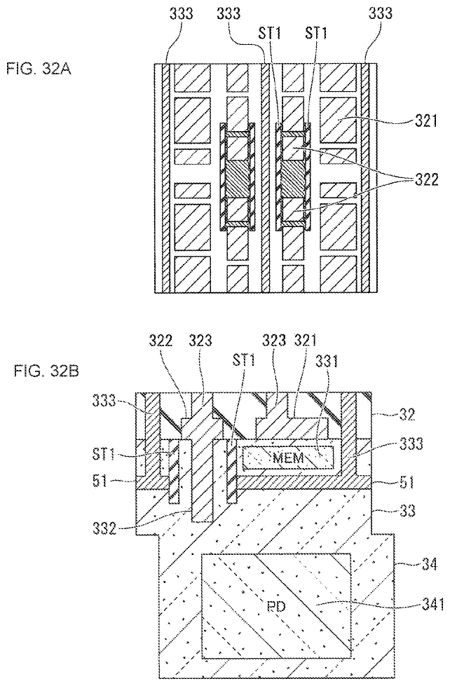

Next, the vertical gate electrode 332 is formed between stoppers ST1 in the MEM layer 33, and furthermore, the transistor base section 321 that configures the second transfer transistor TRM and the transistor base section 322 that configures the first transfer transistor TRX are formed on the top surface (front surface) of the MEM layer 33 (FIG. 31 (b)). Note that, as illustrated in FIG. 31 (a), multiple other transistor base sections 320 are formed on the front surface of the MEM layer 33.

Next, the temporary embedded sections 37 are removed, tungsten (W), for example, is embedded in the trenches H1 and the trenches H2 to thereby form the light-block formation trenches 51 for the light-blocking film 50 and the front-surface pixel separation section 333, and the wiring layer 32 is formed on the front surface of the MEM layer 33 (FIG. 32 (b)). At this point, metal wiring 323 for connecting to other circuits is formed on the transistor base sections 321 and 322. Note that, as illustrated in FIG. 32 (a), the metal wiring 323 is also formed on the top surface of the multiple other transistor base sections 320.

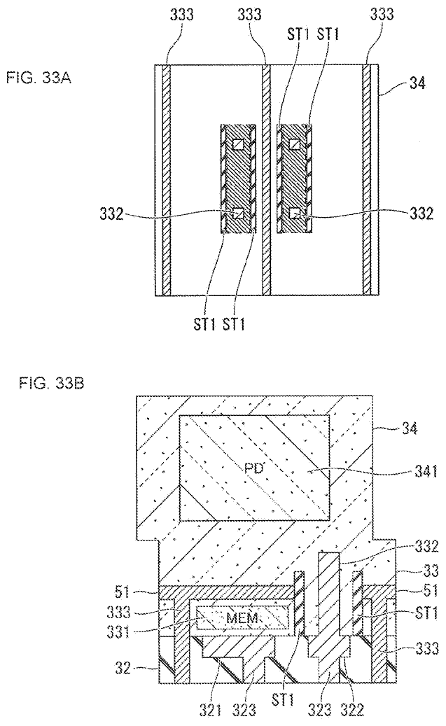

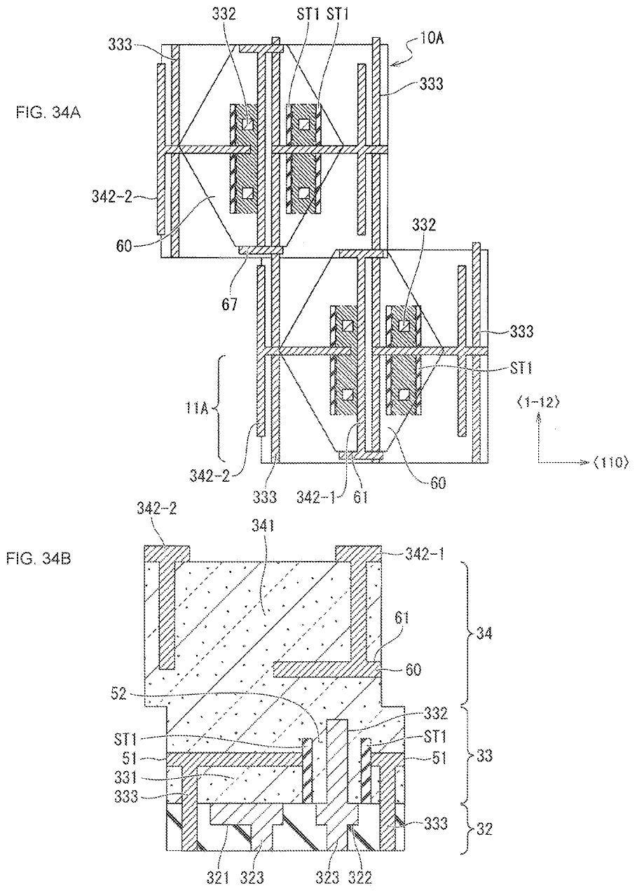

Next, the wiring layer 32, the MEM layer 33, and the photoelectric conversion layer 34 are reversed from the state in FIG. 32 (b), and the photoelectric conversion layer 34 is made thin (FIG. 33). Subsequently, trenches for pixel separation are formed at predetermined locations in the photoelectric conversion layer 34, sidewalls are formed at side walls of the trenches for pixel separation, wet etching using an alkaline solution is used to form trenches for light-blocking films, the sidewalls formed at the side walls of the trenches for pixel separation are removed, and tungsten (W), for example, is embedded in each trench to thereby form the back-surface pixel separation sections 342-1 and 342-2 and the light-block formation trenches 61 for the light-blocking films 60 (FIG. 34 (b)). At this point, as illustrated in FIG. 34 (a), the back-surface pixel separation sections 342-1 and 342-2 are shifted and disposed in the reverse direction to the arrow <110> direction in FIG. 34 (a) with respect to the front-surface pixel separation section 333, according to an image height.

### Fifth Embodiment

In a fifth embodiment of the present disclosure, description is given regarding another embodiment of a two-level light-blocking structure.

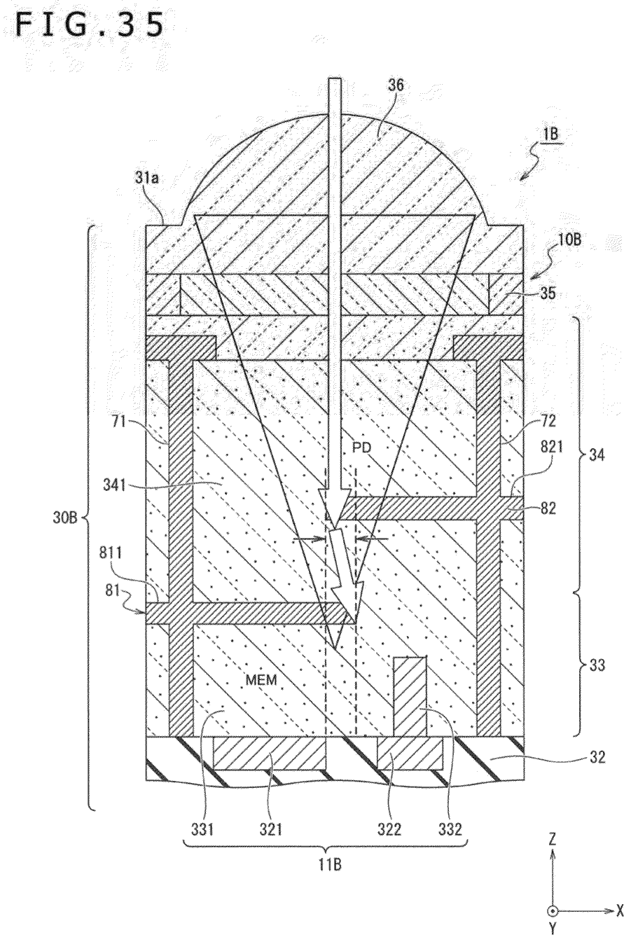

FIG. 35 is a partial cross section of a sensor pixel 11B in a solid-state image capturing apparatus 1B according to a fifth embodiment of the present disclosure. In FIG. 35, the same reference signs are added, and detailed description is omitted for portions that are the same as those in FIG. 3 described above.

In the fifth embodiment of the present disclosure, the sensor pixels 11B are separated from each other, and pixel separation sections 71 and 72 that penetrate the MEM layer 33 and the photoelectric conversion layer 34 can be formed on a first semiconductor substrate 30B for a pixel array section 10B.

A first-level light-blocking film 81 is disposed in the MEM layer 33. The light-blocking film 81 is connected to the pixel separation section 71, and is formed using a light-block formation trench 811 that extends in a direction (direction indicated by the arrow X in FIG. 35) that is orthogonal to the pixel separation section 71. Note that the light-block formation trench 811 may be formed to extend in a direction indicated by the arrow Y in FIG. 35. The light-blocking film 81 blocks incidence of light, which is incident via the light-receiving surface 31a, onto the charge holding region 331.

A second-level light-blocking film 82 is disposed in the photoelectric conversion layer 34. The light-blocking film 82 is connected to the pixel separation section 72, and is formed using a light-block formation trench 821 that extends in a direction (direction indicated by the arrow X in FIG. 35) that is orthogonal to the pixel separation section 72. Note that the light-block formation trench 821 may be formed to extend in a direction indicated by the arrow Y in FIG. 35. The light-blocking film 82 blocks incidence of light, which is incident via the light-receiving surface 31a, onto the charge holding region 331.

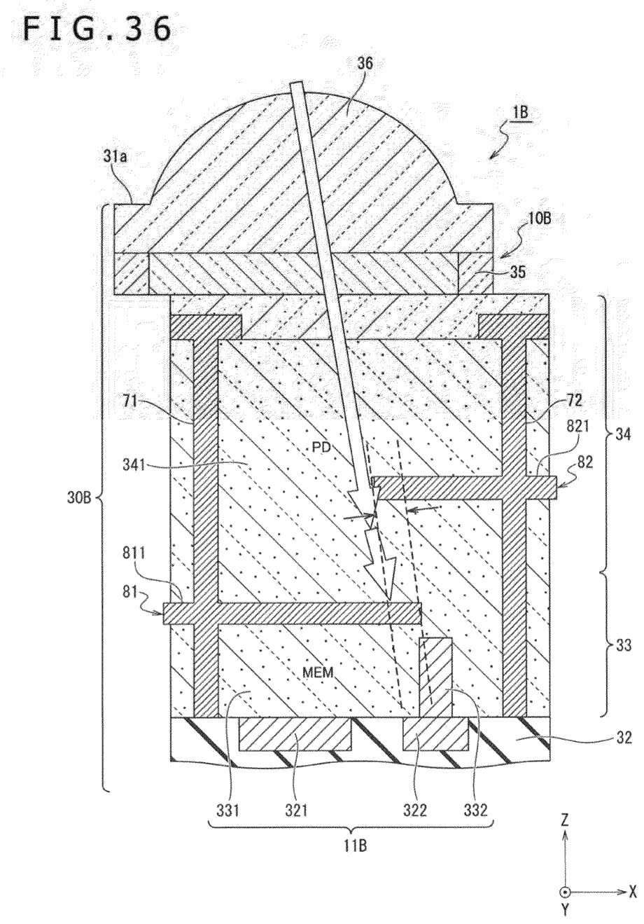

In the fifth embodiment of the present disclosure, it is not possible to correct the MEM layer 33 with respect to the photoelectric conversion layer 34, and thus the amounts of trench protrusion by the first-level light-block formation trench 811 and the second-level light-block formation trench 811 in the direction indicated by the arrow X in FIG. 35 are adjusted, whereby it is possible to adjust the amounts of cover by the light-blocking films 81 and 82 and approach the manner in which light makes contact at the image height center. As illustrated in FIG. 36, the more a position is close to an image height end (the higher the image height), the more the amounts of trench protrusion by the first-level light-block formation trench 811 and the second-level light-block formation trench 811 in the direction indicated by the arrow X in FIG. 35 increase.

### Operation Effect According to the Fifth Embodiment

By virtue of the fifth embodiment as described above, in a case where it is not possible to correct the MEM layer 33 with respect to the photoelectric conversion layer 34, the amounts of trench protrusion by the first-level light-block formation trench 811 and the second-level light-block formation trench 811 in the direction indicated by the arrow X in FIG. 35 are adjusted according to an image height, whereby it is possible to adjust the amounts of cover by the light-blocking films 81 and 82 and approach the manner in which light makes contact at the image height center.

### Sixth Embodiment

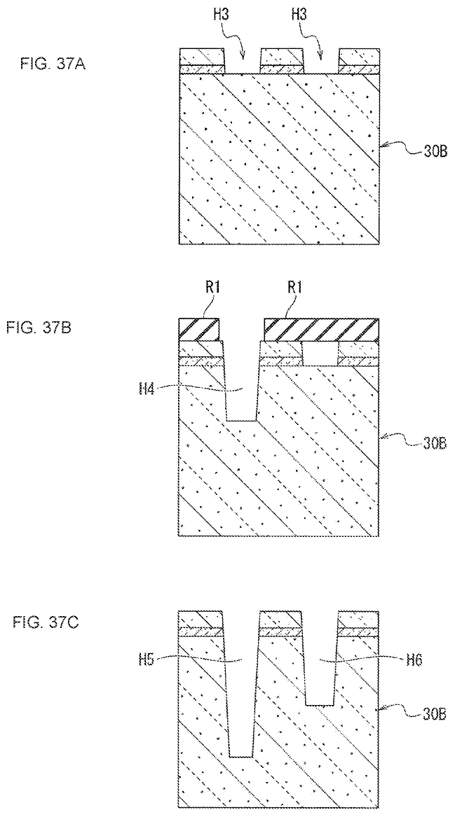

In a sixth embodiment of the present disclosure, description is given regarding a method of manufacturing the solid-state image capturing apparatus 1B that has a two-level light-blocking structure. FIGS. 37 through 42 each represent an example of a manufacturing process in a case of forming light-blocking films from a front surface side of the first semiconductor substrate 30B.

First, the first semiconductor substrate 30B that includes a silicon substrate for which a crystal orientation is (111) is prepared, and hardmask (HM) processing that uses silicon oxide and silicon nitride is performed to thereby form trenches H3 for pixel separation at locations for forming the pixel separation sections 71 and 72 (FIG. 37 (a)). Next, a resist film R1 that includes silicon is deposited on the top surface of the first semiconductor substrate 30B to thereby form a trench H4 that is deeper than the trenches H3 (FIG. 37 (b)), the resist film R1 is removed to thereby form a trench H5 deeper than the trench H3, and a trench H6 shallower than the trench H5 is formed (FIG. 37 (c)).

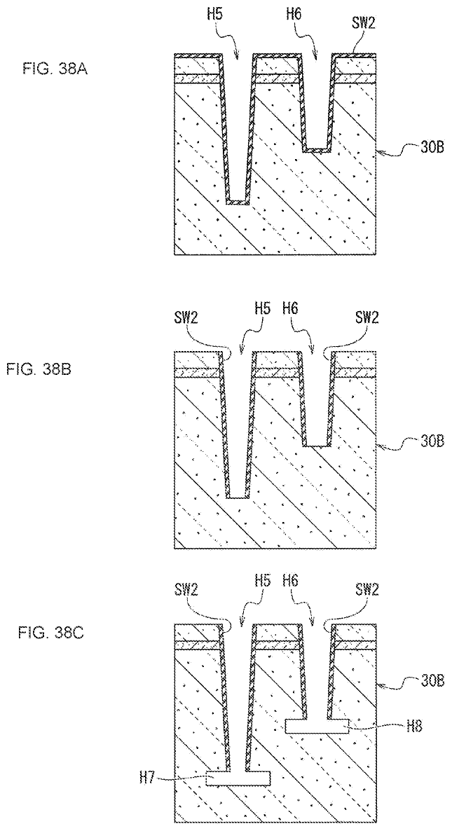

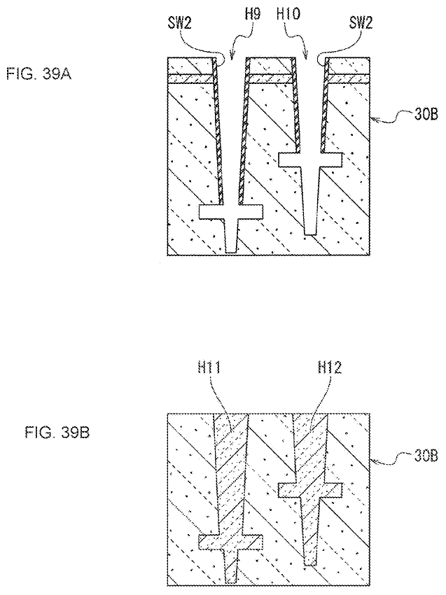

Next, the sidewall SW2 is formed on the side walls of the trenches H5 and H6 (FIG. 38 (a)), the sidewall SW2 formed at the bottom of each of the trenches H5 and H6 is removed (FIG. 38 (b)), and wet etching is used to form a trench H7 for a light-blocking film at the bottom of the trench H5 and form a trench H8 for a light-blocking film at the bottom of the trench H6 (FIG. 38 (c)).

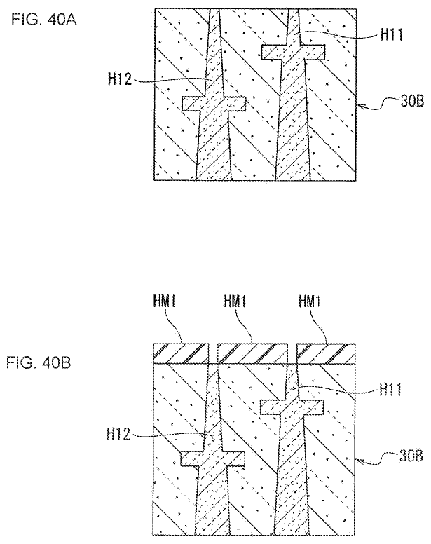

Next, a trench H9 that is even deeper than the trench H5 is formed and a trench H10 that is even deeper than the trench H6 is formed (FIG. 39 (a)), the sidewall SW2 on each of the trenches H9 and H10 is removed, and polysilicon, for example, is embedded in each of the trenches H9 and H10 to thereby form temporary embedded sections H11 and H12 (FIG. 39 (b)).

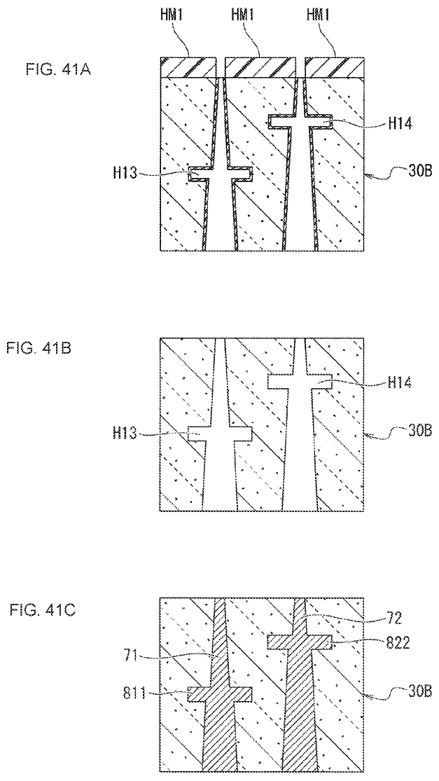

Next, the first semiconductor substrate 30B is reversed and the back surface thereof (the light-receiving surface 31a) is made thin (FIG. 40 (a)), and a hardmask HM1 is deposited on the back surface side of the first semiconductor substrate 30B (FIG. 40 (b)). Subsequently, wet etching using an alkaline solution is used to remove the temporary embedded sections H11 and H12 and thereby form hollow trenches H13 and H14 (FIG. 41 (a)); the hardmask HM1 is removed (FIG. 41 (b)); and tungsten (W), for example, is embedded in the trench H13 to thereby form the pixel separation section 71 and the light-block formation trench 811 for the light-blocking film 81, and tungsten (W), for example, is embedded in the trench H14 to thereby form the pixel separation section 72 and the light-block formation trench 821 for the light-blocking film 82 (FIG. 41 (c)).

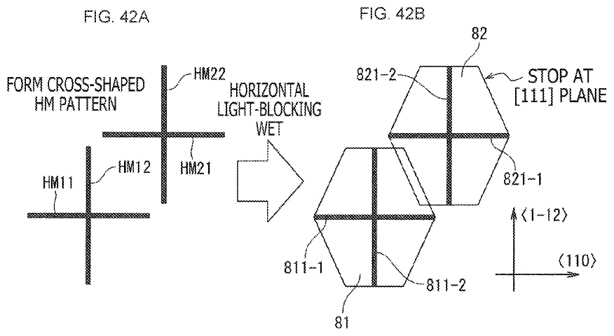

In FIG. 42 (a), in the state illustrated in FIG. 37A described above, cross-shaped hardmask (HM) patterns HM11, HM12, HM21, and HM22 are formed. In FIG. 42 (b), in the state illustrated in FIG. 38 (c) described above, wet etching is used to form the light-blocking films 81 and 82. The light-blocking film 81 is formed in a substantially hexagonal shape by a light-block formation trench 811-1 that extends in the <110> direction, and a light-block formation trench 811-2 that extends in the <1-12> direction. The light-blocking film 82 is formed in a substantially hexagonal shape by a light-block formation trench 821-1 that extends in the <110> direction, and a light-block formation trench 821-2 that extends in the <1-12> direction.

### Seventh Embodiment

In a seventh embodiment of the present disclosure, description is given regarding a case where first-level and second-level light-block formation trenches have cross-shaped patterns.

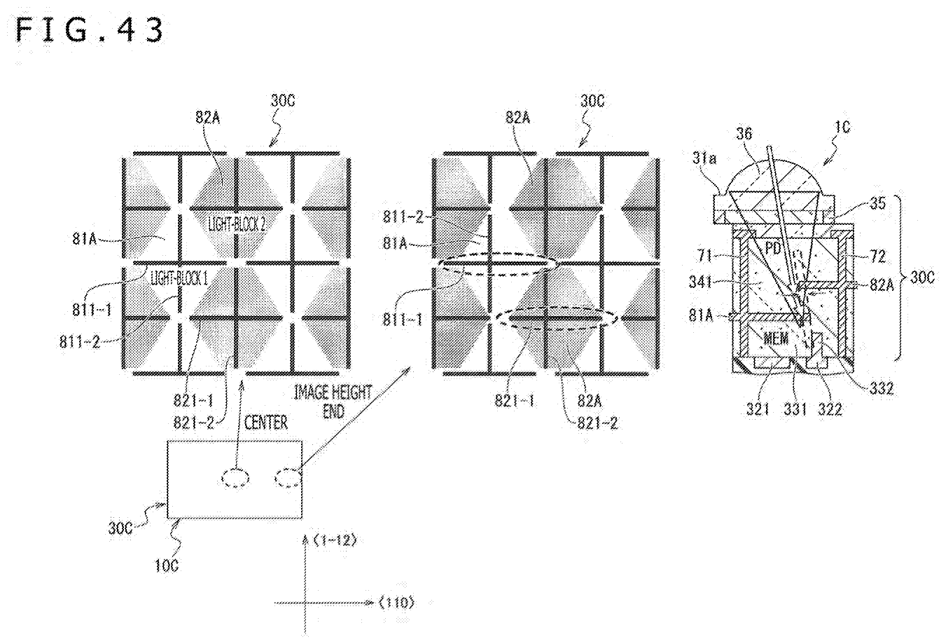

FIG. 43 is a plan view that illustrates, from the back surface side of a first semiconductor substrate 30C, a method for correcting an amount of cover by light-blocking films in a solid-state image capturing apparatus 1C according to the seventh embodiment of the present disclosure. In FIG. 43, the same reference signs are added, and detailed description is omitted for portions that are the same as those in FIG. 35 described above.

In the seventh embodiment of the present disclosure, light-block formation trenches 811-1 and 811-2 that have cross-shaped patterns are connected to a pixel separation section 71. The light-block formation trench 811-1 extends in the arrow <110> direction in FIG. 43, and the light-block formation trench 811-2 extends in the arrow <1-12> direction in FIG. 43. The light-block formation trenches 811-1 and 811-2 form a substantially hexagonal light-blocking film 81A.

In contrast, light-block formation trenches 821-1 and 821-2 that have cross-shaped patterns are connected to a pixel separation section 72. The light-block formation trench 821-1 extends in the arrow <110> direction in FIG. 43, and the light-block formation trench 821-2 extends in the arrow <1-12> direction in FIG. 43. The light-block formation trenches 821-1 and 821-2 form a substantially hexagonal light-blocking film 82A.

In the seventh embodiment of the present disclosure, it is possible to correct the amount of cover itself by the first-level light-blocking film 81A. In this case, the amount of protrusion by the light-block formation trench 811-1 that extends in the <110> direction in the pixel array section 10C is made different between the left and right to thereby correct the amount of cover by the light-blocking film 81A. In other words, the amount of protrusion by a light-block formation trench 811-1 close to an image height end is increased, whereby it is possible to perform a correction to the direction in which light comes into contact with the light-blocking film 81A such that the direction is the same as that for the image height center even if the image height increases.

In addition, it is possible to correct the amount of cover itself for the second-level light-blocking film 82A. In this case, the amount of protrusion by the light-block formation trench 821-1 that extends in the <110> direction is made different between the left and right to thereby correct the amount of cover by the light-blocking film 82A. In other words, the amount of protrusion by a light-block formation trench 821-1 close to an image height end is increased, whereby it is possible to perform a correction to the direction in which light comes into contact with the light-blocking film 82A such that the direction is the same as that for the image height center even if the image height increases.

In the case of a two-level light-blocking structure, light blocking deeper from the light-receiving surface 31a has a larger eccentricity for a light-condensing spot, and thus an amount of correction also increases. Accordingly, the amount of correction for the first-level light-blocking film 81A becomes greater than the amount of correction for the second-level light-blocking film 82A.

### Operation Effect According to the Seventh Embodiment

By virtue of the seventh embodiment as above, according to the image height, the amount of protrusion by the first-level light-block formation trench 811-1 that extends in the <110> direction is made different between the left and right and the amount of protrusion by the second-level light-block formation trench 821-1 that extends in the <110> direction is made different between the left and right, whereby it is possible to correct the amounts of cover by the first-level light-blocking film 81A and the second-level light-blocking film 82A.

### Eighth Embodiment

In an eighth embodiment of the present disclosure, description is given regarding a case where first-level light-block formation trenches have cross-shaped patterns.

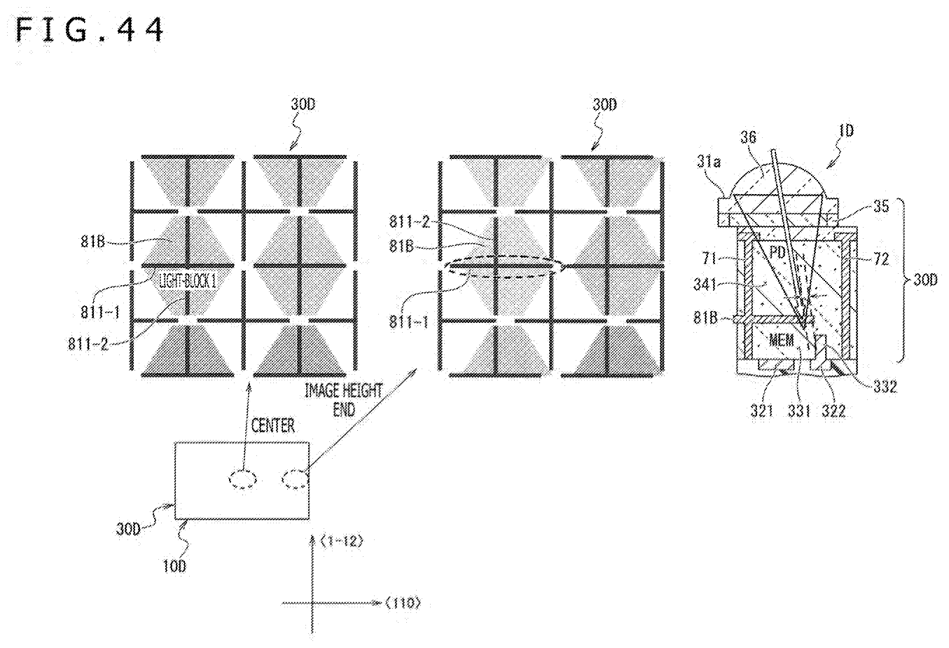

FIG. 44 is a plan view that illustrates, from the back surface side of a first semiconductor substrate 30D, a method for correcting an amount of cover by light-blocking films in a solid-state image capturing apparatus 1D according to the eighth embodiment of the present disclosure. In FIG. 44, the same reference signs are added, and detailed description is omitted for portions that are the same as those in FIG. 35 described above.

In the eighth embodiment of the present disclosure, light-block formation trenches 811-1 and 811-2 that have cross-shaped patterns are connected to a pixel separation section 71. In a pixel array section 10D, the light-block formation trench 811-1 extends in the arrow <110> direction in FIG. 44, and the light-block formation trench 811-2 extends in the arrow <1-12> direction in FIG. 44. The light-block formation trenches 811-1 and 811-2 form a substantially hexagonal light-blocking film 81B.

In the eighth embodiment of the present disclosure, it is possible to correct the amount of cover itself by the first-level light-blocking film 81B. In this case, the amount of protrusion by the light-block formation trench 811-1 that extends in the <110> direction is made different between the left and right to thereby correct the amount of cover by the light-blocking film 81B. In other words, the amount of protrusion by a light-block formation trench 811-1 close to an image height end is increased, whereby it is possible to perform a correction to the direction in which light comes into contact with the light-blocking film 81B such that the direction is the same as that for the image height center even if the image height increases.

### Operation Effect According to the Eighth Embodiment

In addition, by virtue of the eighth embodiment as above, the amount of protrusion in the <110> direction by a light-block formation trench 811-1 close to an image height end is increased, whereby it is possible to perform a correction to the direction in which light comes into contact with a light-blocking section such that the direction is the same as that for the image height center even if the image height increases.

### OTHER EMBODIMENTS

As described above, the present technique is described according to the first through eighth embodiments as well as the first variation and the second variation of the third embodiment, but statements and drawings that form a portion of this disclosure should not be understood as limiting the present technique. If the gist of the technical content disclosed by the first through eighth embodiments described above is understood, it would be clear to a person skilled in the art that various alternative embodiments, examples, and operational techniques can be included in the present technique. In addition, configurations respectively disclosed by the first through eighth embodiments and the first variation and the second variation of the third embodiment can be combined, as appropriate, in a scope where inconsistency does not arise. For example, configurations respectively disclosed by multiple different embodiments may be combined, or configurations respectively disclosed by multiple different variations of the same embodiment may be combined.

It is to be noted that the present disclosure can also adopt the following configurations.

(1)

A solid-state image capturing apparatus including:
a semiconductor substrate in which multiple pixels are disposed in a matrix, in which
each of the multiple pixels is provided with
   a photoelectric conversion unit that generates charge according to photoelectric conversion based on light incident on a light-receiving surface of the semiconductor substrate,
   a charge accumulating unit that accumulates the charge generated by the photoelectric conversion unit,
   a transfer transistor that transfers charge from the photoelectric conversion unit to the charge accumulating unit and has a vertical gate electrode that reaches the photoelectric conversion unit, and
   a light-blocking section that is formed by a trench disposed within a layer between the light-receiving surface and the charge accumulating unit and blocks light that is incident via the light-receiving surface from being incident on the charge accumulating unit, and
an amount of cover by the light-blocking section with respect to the charge accumulating unit is corrected according to an image height of a position where the pixel is disposed.
   (2)

The solid-state image capturing apparatus according to (1) above, in which
the photoelectric conversion unit is, according to the image height, shifted and disposed in a predetermined direction with respect to the charge accumulating unit.
   (3)

The solid-state image capturing apparatus according to (1) above, further including:
a pixel separation section that is connected to the trench for the light-blocking section and electrically and optically separates adjacent pixels.
   (4)

The solid-state image capturing apparatus according to (3) above, in which
the light-blocking section is formed by a trench that extends in a direction orthogonal to the pixel separation section.
   (5)

The solid-state image capturing apparatus according to (4) above, in which
the light-blocking section is formed, in the semiconductor substrate for which a crystal orientation is (111), by a trench that extends in a <1-12> direction and a trench that extends in a <110> direction orthogonal to the <1-12> direction, and a length of the trench in the <110> direction differs between the left and right according to the image height.
   (6)

The solid-state image capturing apparatus according to (5) above, in which
the more the light-blocking section is separated from an image height center, the more the trench is longer in the <110> direction.
   (7)

The solid-state image capturing apparatus according to (1) above, in which
the light-blocking section has an opening through which the vertical gate electrode penetrates.
   (8)

The solid-state image capturing apparatus according to (1) above, in which
the light-blocking section has an opening through which the vertical gate electrode penetrates, and
the opening is shifted with respect to the pixel separation section according to the image height.
   (9)

The solid-state image capturing apparatus according to (8) above, in which
an amount by which the opening in the light-blocking section is shifted with respect to the pixel separation section increases as the opening in the light-blocking section is away from an image height center.
   (10)

A solid-state image capturing apparatus including:
a semiconductor substrate in which multiple pixels are disposed in a matrix, in which
each of the multiple pixels is provided with
   a photoelectric conversion unit that generates charge according to photoelectric conversion based on light incident on a light-receiving surface of the semiconductor substrate,
   a charge accumulating unit that accumulates the charge generated by the photoelectric conversion unit,
   a transfer transistor that transfers charge from the photoelectric conversion unit to the charge accumulating unit and has a vertical gate electrode that reaches the photoelectric conversion unit,
   a first light-blocking section that is formed by a trench disposed within a layer between the photoelectric conversion unit and the charge accumulating unit and blocks light that is incident via the light-receiving surface from being incident on the charge accumulating unit, and
   a second light-blocking section that is formed by a trench disposed within a layer between the light-receiving surface and the first light-blocking section and blocks light that is incident via the light-receiving surface from being incident on the charge accumulating unit, and
amounts of cover by the first and second light-blocking sections with respect to the charge accumulating unit are corrected according to an image height of a position where the pixel is disposed.
   (11)

The solid-state image capturing apparatus according to (10) above, further including:
a pixel separation section that is connected to the first light-blocking section and the second light-blocking section and electrically and optically separates adjacent pixels.
   (12)

The solid-state image capturing apparatus according to (11) above, in which
the first and second light-blocking sections are formed by trenches that extend in a direction orthogonal to the pixel separation section.
   (13)

The solid-state image capturing apparatus according to (12) above, in which
the first and second light-blocking sections are each formed, in the semiconductor substrate for which a crystal orientation is (111), by a trench that extends in a <1-12> direction and a trench that extends in a <110> direction orthogonal to the <1-12> direction, and a length of the trench in the <110> direction differs between the left and right according to the image height.
   (14)

The solid-state image capturing apparatus according to (13) above, in which
the more the first and second light-blocking sections are separated from an image height center, the more the trenches are longer in the <110> direction.
   (15)

The solid-state image capturing apparatus according to (13) above, in which
an amount of correction in the <110> direction for the first light-blocking section is greater than an amount of correction in the <110> direction for the second light-blocking section.
   (16)

The solid-state image capturing apparatus according to (10) above, in which
the first light-blocking section has an opening through which the vertical gate electrode penetrates.
   (17)

The solid-state image capturing apparatus according to (16) above, in which
the second light-blocking section is shifted, according to the image height, with respect to the opening in the first light-blocking section.
   (18)

The solid-state image capturing apparatus according to (17) above, in which
an amount by which the second light-blocking section is shifted with respect to the opening in the first light-blocking section increases as the second light-blocking section is away from an image height center.
   (19)

The solid-state image capturing apparatus according to (18) above, in which
an amount of correction with respect to the pixel separation section for the opening in the first light-blocking section is greater than an amount of correction for the second light-blocking section.

### REFERENCE SIGNS LIST

1, 1A, 1B, 1C, 1D: Solid-state image capturing apparatus
10, 10A, 10B, 10C, 10D: Pixel array section
11, 11A, 11B: Sensor pixel
20: Logic circuit
21: Vertical drive circuit
22: Wiring layer
22: Column signal processing circuit
23: Horizontal drive circuit
24: System control circuit
30, 30A, 30B, 30C, 30D: First semiconductor substrate
31a: Light-receiving surface
32: Wiring layer
33: MEM layer
34: Photoelectric conversion layer
35: Color filter
36: On-chip lens
37: Temporary embedded section
40: Second semiconductor substrate
50: Light-blocking film
51: Light-block formation trench
52: Opening
60, 60A, 60B: Light-blocking film
61, 61A, 61B1, 61B2: Light-block formation trench
71, 72: Pixel separation section
81, 81A, 81B, 82, 82A: Light-blocking film
320, 321, 322: Transistor base section
323: Metal wiring
331: Charge holding region
332: Vertical gate electrode
333: Front-surface pixel separation section
341: Photoelectric conversion element
342, 342-1, 342-2: Back-surface pixel separation section
811: Light-block formation trench
811-1, 811-2, 821, 821-1, 821-2: Light-block formation trench

1. A solid-state image capturing apparatus comprising:
a semiconductor substrate in which multiple pixels are disposed in a matrix, wherein
each of the multiple pixels is provided with
a photoelectric conversion unit that generates charge according to photoelectric conversion based on light incident on a light-receiving surface of the semiconductor substrate,
a charge accumulating unit that accumulates the charge generated by the photoelectric conversion unit,
a transfer transistor that transfers charge from the photoelectric conversion unit to the charge accumulating unit and has a vertical gate electrode that reaches the photoelectric conversion unit, and
a light-blocking section that is formed by a trench disposed within a layer between the light-receiving surface and the charge accumulating unit and blocks light that is incident via the light-receiving surface from being incident on the charge accumulating unit, and
an amount of cover by the light-blocking section with respect to the charge accumulating unit is corrected according to an image height of a position where the pixel is disposed.

2. The solid-state image capturing apparatus according to claim 1, wherein
the photoelectric conversion unit is, according to the image height, shifted and disposed in a predetermined direction with respect to the charge accumulating unit.

3. The solid-state image capturing apparatus according to claim 1, further comprising:
a pixel separation section that is connected to the trench for the light-blocking section and electrically and optically separates adjacent pixels.

4. The solid-state image capturing apparatus according to claim 3, wherein
the light-blocking section is formed by a trench that extends in a direction orthogonal to the pixel separation section.

5. The solid-state image capturing apparatus according to claim 4, wherein
the light-blocking section is formed, in the semiconductor substrate for which a crystal orientation is (111), by a trench that extends in a <1-12> direction and a trench that extends in a <110> direction orthogonal to the <1-12> direction, and a length of the trench in the <110> direction differs between the left and right according to the image height.

6. The solid-state image capturing apparatus according to claim 5, wherein
the more the light-blocking section is separated from an image height center, the more the trench is longer in the <110> direction.

7. The solid-state image capturing apparatus according to claim 1, wherein
the light-blocking section has an opening through which the vertical gate electrode penetrates.

8. The solid-state image capturing apparatus according to claim 1, wherein
the light-blocking section has an opening through which the vertical gate electrode penetrates, and
the opening is shifted with respect to the pixel separation section according to the image height.

9. The solid-state image capturing apparatus according to claim 8, wherein
an amount by which the opening in the light-blocking section is shifted with respect to the pixel separation section increases as the opening in the light-blocking section is away from an image height center.

10. A solid-state image capturing apparatus comprising:
a semiconductor substrate in which multiple pixels are disposed in a matrix, wherein
each of the multiple pixels is provided with
a photoelectric conversion unit that generates charge according to photoelectric conversion based on light incident on a light-receiving surface of the semiconductor substrate,
a charge accumulating unit that accumulates the charge generated by the photoelectric conversion unit,
a transfer transistor that transfers charge from the photoelectric conversion unit to the charge accumulating unit and has a vertical gate electrode that reaches the photoelectric conversion unit,
a first light-blocking section that is formed by a trench disposed within a layer between the photoelectric conversion unit and the charge accumulating unit and blocks light that is incident via the light-receiving surface from being incident on the charge accumulating unit, and
a second light-blocking section that is formed by a trench disposed within a layer between the light-receiving surface and the first light-blocking section and blocks light that is incident via the light-receiving surface from being incident on the charge accumulating unit, and
amounts of cover by the first and second light-blocking sections with respect to the charge accumulating unit are corrected according to an image height of a position where the pixel is disposed.

11. The solid-state image capturing apparatus according to claim 10, further comprising:
a pixel separation section that is connected to the first light-blocking section and the second light-blocking section and electrically and optically separates adjacent pixels.

12. The solid-state image capturing apparatus according to claim 11, wherein
the first and second light-blocking sections are formed by trenches that extend in a direction orthogonal to the pixel separation section.

13. The solid-state image capturing apparatus according to claim 12, wherein
the first and second light-blocking sections are each formed, in the semiconductor substrate for which a crystal orientation is (111), by a trench that extends in a <1-12> direction and a trench that extends in a <110> direction orthogonal to the <1-12> direction, and a length of the trench in the <110> direction differs between the left and right according to the image height.

14. The solid-state image capturing apparatus according to claim 13, wherein
the more the first and second light-blocking sections are separated from an image height center, the more the trenches are longer in the <110> direction.

15. The solid-state image capturing apparatus according to claim 13, wherein
an amount of correction in the <110> direction for the first light-blocking section is greater than an amount of correction in the <110> direction for the second light-blocking section.

16. The solid-state image capturing apparatus according to claim 10, wherein
the first light-blocking section has an opening through which the vertical gate electrode penetrates.

17. The solid-state image capturing apparatus according to claim 16, wherein
the second light-blocking section is shifted, according to the image height, with respect to the opening in the first light-blocking section.

18. The solid-state image capturing apparatus according to claim 17, wherein
an amount by which the second light-blocking section is shifted with respect to the opening in the first light-blocking section increases as the second light-blocking section is away from an image height center.

19. The solid-state image capturing apparatus according to claim 18, wherein
an amount of correction with respect to a pixel separation section for the opening in the first light-blocking section is greater than an amount of correction for the second light-blocking section.
